(19) United States
(12) Patent Application Publication
(10) Pub. No.: US 2011/0226178 A1
(43) Pub. Date: Sep. 22, 2011

(54) FILM DEPOSITION SYSTEM

(75) Inventors: Norihiko TSUJI, Nirasaki-Shi (JP); Masayuki Moroi, Nirasaki-Shi (JP); Atsushi Sawachi, Nirasaki-Shi (JP); Sasumu Katoh, Nirasaki-Shi (JP)

(73) Assignee: TOKYO ELECTRON LIMITED, TOKYO-TO (JP)

(21) Appl. No.: 13/074,261

(22) Filed: Mar. 29, 2011

Related U.S. Application Data
(63) Continuation of application No. PCT/JP2009/066937, filed on Sep. 29, 2009.

(30) Foreign Application Priority Data
Sep. 30, 2008 (JP) 2008-254554

(51) Int. Cl. C23C 14/00

(52) U.S. Cl. 118/50

(57) ABSTRACT

A film deposition system which a cycle of alternately supplying a first reactive gas and a second reactive gas and exhausting them is repeated twice or more in a vacuum vessel to cause reaction between the two gases, thereby depositing thin films on substrate surfaces, the film deposition system includes: a plurality of lower members having substrate-placing areas on which substrates will be placed; a plurality of upper members so placed that they face the lower members to form processing spaces together with the substrate-placing areas; a first reactive gas supply unit and a second reactive gas supply unit for supplying a first reactive gas and a second reactive gas, respectively, to the processing spaces; a purge gas supply unit for supplying a purge gas in the period between a first reactive gas supply period and a second reactive gas supply period; exhaust openings, situated along circumferences of the processing spaces, for communicating the inside of the processing spaces with the atmosphere in the vacuum vessel that is outside of the processing spaces; and an evacuating unit for evacuating the processing spaces via the atmosphere in the exhaust openings and the vacuum vessel.

### BACKGROUND OF THE INVENTION

1.Field of the Invention

The present invention relates to a film deposition system for forming a thin film by depositing a large number of layers of a reaction product of a first reactive gas and a second reactive gas by repeating many times a cycle of supplying the two gases alternately and exhausting them.

2. Background Art

There has been known the following deposition process as a film deposition technique for use in the process of semiconductor production. A first reactive gas is supplied to the surface of a semiconductor wafer (hereinafter referred to as a “wafer”) or the like as a substrate, under a vacuum, to allow the surface to adsorb the first reactive gas, and then the supplying gas is changed from the first reactive gas to a second reactive gas to cause reaction between the two reactive gases, thereby depositing one, or two or more, atomic or molecular layers on the substrate; this cycle is repeated many times to form a multi-layered film on the substrate. This process is called ALD (Atomic Layer Deposition), MLD (Molecular Layer Deposition), etc.; since it makes possible very precise control of film thickness by changing the number of the cycles and also deposition of a film that is uniform in film quality over its surface, it is a technique that can meet the demand for semiconductor devices smaller in thickness.

One of the cases where the above deposition process is suitably used is the deposition of high-dielectric films for use as e.g., gate oxide films. For example, in order to deposit a silicon oxide film (SiO₂ film), e.g., bis-tert-butylaminosilane (hereinafter referred to as “BTBAS”) gas is used as the first reactive gas (depositing material gas) and e.g., oxygen gas as the second reactive gas.

To perform the above film deposition process is used a film deposition system of single wafer processing type having a gas shower head placed above the center of a vacuum vessel. There has been discussed the embodiment that reactive gases are supplied to a substrate from above its center, while the unreacted gases and by-products are exhausted from the bottom of the processing vessel. This film deposition process, however, is at a disadvantage in that it requires a long time for replacement of the reactive gases with purge gas, and also a long time for the process itself because a cycle of gas supply and evacuation has to be repeated many times, e.g., several hundred times. Moreover, each time the process for a single substrate is conducted, it is necessary to transport a substrate to and from the processing vessel and evacuate the processing vessel; these operations entail a great time loss.

There is known a system for depositing films on the surfaces of substrates by placing a plurality of substrates on a discal table in its circumferential direction and alternately supplying reactive gases to the substrates on the rotating table, as described in Japanese Patent Publication No. 3144664 (particularly FIGS. 1 and 2, and claim 1) and Japanese Laid-Open Patent Publication No. 2001-254181 (particularly FIGS. 1 and 2). For example, the film deposition system described in Japanese Patent Publication No. 3144664 has a plurality of sectioned processing spaces in the direction of the circumference of the table, to which different reactive gases will be supplied. On the other hand, the film deposition system described in Japanese Laid-Open Patent Publication No. 2001-254181 has reactive gas supply nozzles, e.g., two, extending over the table along its diameter, for discharging different reactive gases toward the table. By rotating the table, the substrates on it are allowed to pass through the processing space or the space under the reactive gas supply nozzles, whereby the reactive gases are alternately supplied to each substrate to form a film on it. These film deposition systems do not require the step of purging the reactive gases and can process a plurality of substrates by conducting only once the operation for carrying substrates in and out of the processing vessel and the operation for evacuation. The time required for these step and operation is therefore reduced for the film deposition systems, which leads to improvement in throughput.

In recent years, larger-sized substrates have come to be demanded, and, in the case of e.g., semiconductor wafers (hereinafter referred to as “wafers”), film deposition has to be conducted on a substrate with a diameter of as large as 300 mm. When a plurality of large-sized wafers are placed on one table, a relatively large space is formed between each two adjacent wafers. The reactive gases supplied from the reactive gas supply nozzles flow even in these spaces, which leads to increase in the consumption of the reactive gases that do not take part in film deposition.

Now, suppose discal wafers with a diameter of 300 mm are placed on a table on the circumference of a circle with a diameter of 150 mm, concentric with the table, in such a manner that each two adjacent wafers are circumscribed, and this table is rotated at a speed of 60 rpm. In this case, the rate of the wafer movement in the direction of the circumference of the table comes to differ about three times on two sides, the center side and the outer edge side of the table. This means that the difference in the rate of movement among various portions of each wafer passing under the reactive gas supply nozzles also reaches a maximum of three times depending on the respective positions of the portions on the table.

If the concentration of the reactive gas supplied from the reactive gas supply nozzle is constant along the diameter of the table, the amount of the reactive gas that can take part in the deposition of a film on the wafer surface decreases as the rate at which the wafer passes under the nozzle increases. For this reason, the amount of the reactive gas to be supplied from the nozzle is determined so that the reactive gas concentration required to deposit a film on a portion of the wafer surface that is situated on the edge side of the table, on which the rate at which the wafer passes under the reactive gas supply nozzle becomes highest, can be obtained. If the reactive gas is supplied in the amount required to form a film on the portion situated on the edge side of the table, on which the passing rate is highest, the reactive gas is to be supplied to the portion situated on the center side of the table, on which the passing rate is lower than on the edge side, at a concentration higher than necessary. Consequently, the reactive gas is partially exhausted as it is without taking part in film deposition. Depositing material gases for use in ALD or the like are often obtained by vaporizing liquid depositing materials, or by subliming solid depositing materials, and these depositing materials are expensive. Therefore, although the above-described film deposition systems in which the table is rotated are improved in wafer throughput, they have the drawback that they consume expensive reactive gases in amounts more than necessary for film deposition.

### SUMMARY OF THE INVENTION

In the light of the above drawbacks in the prior art, the present invention was accomplished. Accordingly, an object of the present invention is to provide a film deposition system that is improved in throughput and that consumes reactive gases less than ever.

The present invention is a film deposition system which a cycle of alternately supplying a first reactive gas and a second reactive gas and exhausting them is repeated twice or more in a vacuum vessel to cause reaction between the two gases, thereby depositing thin films on substrate surfaces, the film deposition system including, in the vacuum vessel: a plurality of lower members having substrate-placing areas on which substrates will be placed; a plurality of upper members so placed that they face the lower members to form processing spaces together with the substrate-placing areas; a first reactive gas supply unit and a second reactive gas supply unit for supplying a first reactive gas and a second reactive gas, respectively, to the processing spaces; a purge gas supply unit for supplying a purge gas in the period between a first reactive gas supply period and a second reactive gas supply period; exhaust openings, situated along circumferences of the processing spaces, for communicating the inside of the processing spaces with the atmosphere in the vacuum vessel that is outside of the processing spaces; and an evacuating unit for evacuating the processing spaces via the atmosphere in the exhaust openings and the vacuum vessel.

According to the present invention, the film deposition system for depositing thin films by means of a so-called ALD (or MLD) process, in which the first reactive gas and the second reactive gas are alternately supplied to a substrate to deposit thereon a thin film, has the following structure: the lower member having a substrate-placing area and the upper member are so placed that they face each other to form a processing space between them; the plurality of pairs of the lower and the upper members are arranged in the vacuum vessel; and the processing spaces are evacuated through the exhaust openings. Such a film deposition system of the present invention can therefore have a smaller total volume of the processing spaces as compared with a conventional system obtained by preparing a large rotatable table on which a plurality of substrates can be placed and forming a common processing space above the rotatable table. Moreover, in the film deposition system of the invention, the reactive gases do not flow in those areas that are not concerned with film deposition, such as the spaces between the substrates, so that the supply amounts of the reactive gases for film deposition can be decreased. The film deposition system therefore can deposit films at a lower cost. Further, since the total volume of the processing spaces in the deposition system of the invention is small, the time required to supply the reactive gases to the processing spaces and also the time required to exhaust the reactive gases from the processing spaces are less than ever, which leads to decrease in the total film deposition time. Namely, that the total volume of the processing spaces is small can also make the film deposition system improved in throughput.

Preferably, the upper member has an inner surface whose transversal section is increased from the top to the bottom.

In addition, preferably, the exhaust opening is a gap circumferentially formed between a bottom edge of the upper member and the lower member.

In addition, preferably, the upper member has, in its center, a gas supply opening through which the first reactive gas, the second reactive gas, and the purge gas are supplied.

In addition, preferably, a plurality of pairs of the upper and the lower members are circumferentially arranged in the vacuum vessel.

In addition, preferably, the film deposition system further comprises a common rotating unit for integrally rotating the pairs of the upper and the lower members that are circumferentially arranged in the vacuum vessel, in the circumferential direction so that delivery of a substrate can be made between a substrate transportation unit located outside the vacuum vessel and the substrate-placing area through a delivery opening provided in a sidewall of the vacuum vessel.

In addition, preferably, the film deposition system further comprises an elevating unit for raising and lowering the lower member relative to the upper member in order to form a space necessary for delivery of a substrate between a substrate transportation unit located outside the vacuum vessel and the substrate-placing area. In this case, it is preferable that the elevating unit be a common one to be used for all the lower members.

### BRIEF DESCRIPTION OF THE DRAWINGS

FIG. 1 is a longitudinal sectional view of a film deposition system according to an embodiment of the present invention.

FIG. 2 is a perspective view showing an inner structure of the film deposition system of this embodiment.

FIG. 3 is a cross-sectional view of the film deposition system of this embodiment.

FIG. 4 is a longitudinal sectional view showing a processing area in the film deposition system of this embodiment.

FIG. 5 is a bottom end view of a top plate member constituting the processing area shown in FIG. 4.

FIG. 6 is a longitudinal sectional view of an injector.

FIG. 7 is a chart showing gas supply routes in the film deposition system of this embodiment.

FIG. 8 is a first operational view of the film deposition system of this embodiment.

FIG. 9A is a second operational view of the film deposition system of this embodiment.

FIG. 9B is a second operational view of the film deposition system of this embodiment.

FIG. 10A is a diagram showing a sequence of gas supply in film deposition that is conducted by the film deposition system of this embodiment.

FIG. 10B is a diagram showing a sequence of gas supply in film deposition that is conducted by the film deposition system of this embodiment.

FIG. 11 is a view showing how a gas flows from a manifold unit to a processing space.

FIG. 12 is a third operational view of the film deposition system of this embodiment.

FIG. 13A is a diagram concerning the operation of the film deposition system of this embodiment.

FIG. 13B is a diagram concerning the operation of the film deposition system of this embodiment.

FIG. 13C is a diagram concerning the operation of the film deposition system of this embodiment.

FIG. 14A is a cross-sectional view showing a modification of the film deposition system of this embodiment.

FIG. 14B is a longitudinal sectional view of the film deposition system shown in FIG. 14A.

FIG. 15 is a longitudinal sectional view showing another modification of the film deposition system of this embodiment.

FIG. 16 is a longitudinal sectional view showing another example of the table and the top plate member.

FIG. 17A is a view illustrating a further example of the top plate member.

FIG. 17B is a view illustrating a still further example of the top plate member.

FIG. 18A is a view illustrating a further example of the table.

FIG. 18B is a view illustrating a still further example of the table.

FIG. 19 is a longitudinal sectional view showing a further example of the film deposition system.

FIG. 20 is a longitudinal sectional view showing a still further example of the film deposition system.

FIG. 21A is a view illustrating another example of the manifold unit.

FIG. 21B is a view illustrating a further example of the manifold unit.

FIG. 22 is a perspective view of the film deposition system set up on a supporting member.

FIG. 23A is a perspective view of a base plate, viewed from the bottom.

FIG. 23B is a perspective view of a holding member, viewed from the top.

FIG. 24 is a view showing descending movement of the base plate of the vacuum vessel in the film deposition system.

FIG. 25 is a perspective view showing the tables and the base plate drawn out of the space under the vacuum vessel.

FIG. 26 is a perspective view of the vacuum vessel with the base plate removed, viewed from the bottom.

FIG. 27 is a view showing a vacuum processing system containing the film deposition systems.

### DETAILED DESCRIPTION OF THE INVENTION

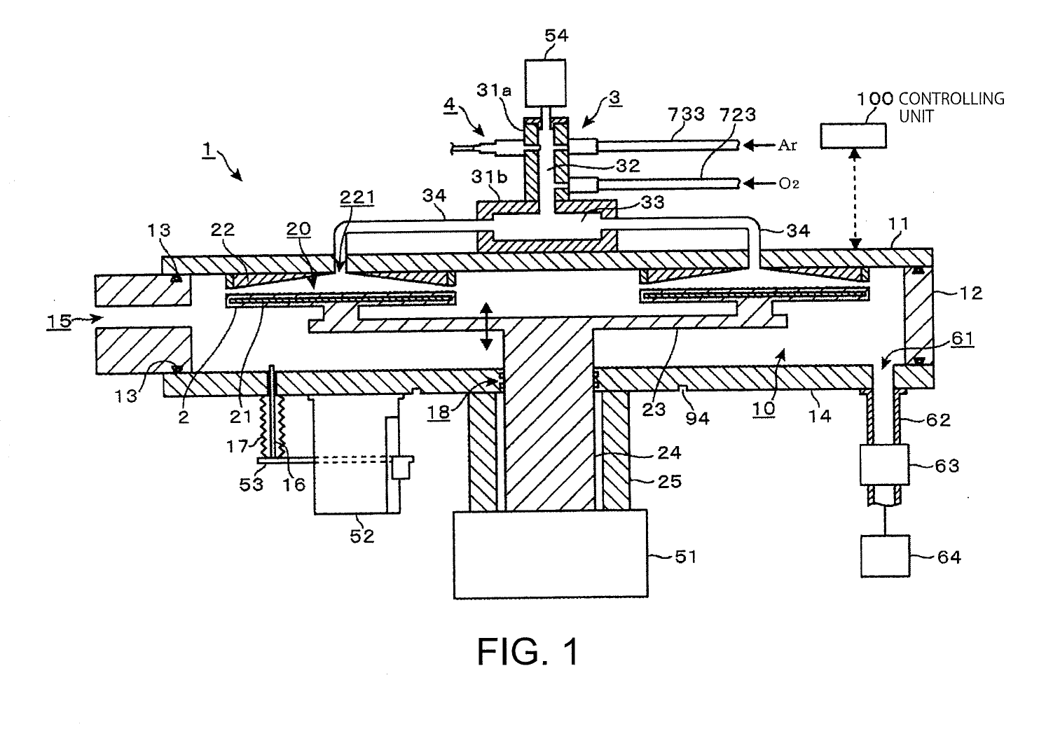

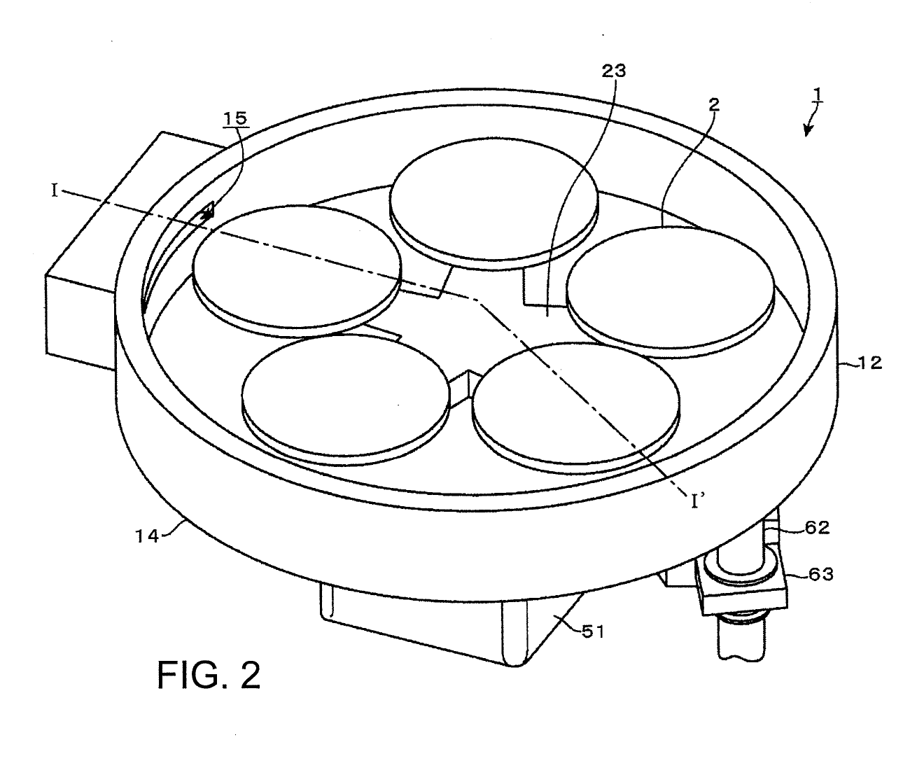

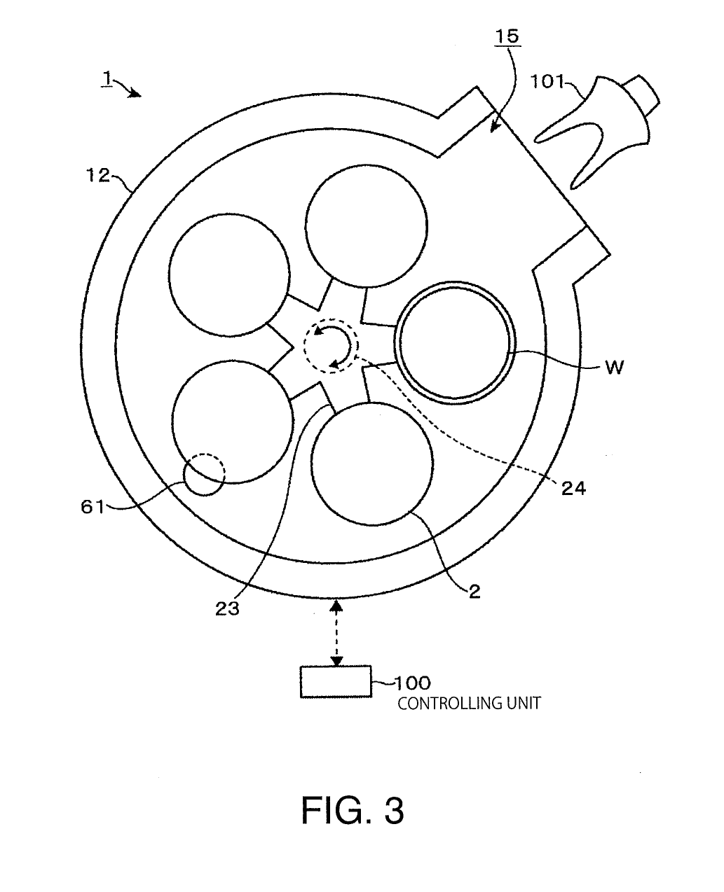

A film deposition system according to an embodiment of the present invention comprises, as shown in FIG. 1 (a longitudinal sectional view taken on line I-I′ in FIG. 2), FIG. 2 and FIG. 3, a vacuum vessel 1 that is flat and whose planar shape is generally circular; a plurality of tables 2, e.g., five, arranged in the vacuum vessel 1 in the direction of the circumference of the vacuum vessel 1; top plate members 22 that are upper members so placed that they face the tables 2 to form processing spaces between the members 22 and the tables 2. In this example, the tables 2 are lower members having substrate-placing areas on which substrates will be placed. The vacuum vessel 1 is composed of a top plate 11, a base plate 14 and a sidewall 12, the former two being separable from the latter. The top plate 11 and the base plate 14 are airtightly fixed to the sidewall 12 with fasteners such as screws, not shown in the figures, via sealing members such as O-rings 13.

When separating the top plate 11 and the base plate 14 from the sidewall 12, the top plate 11 can be raised by a driving mechanism not shown in the figures, and the base plate 14 can be lowered by an elevating mechanism that will be described later.

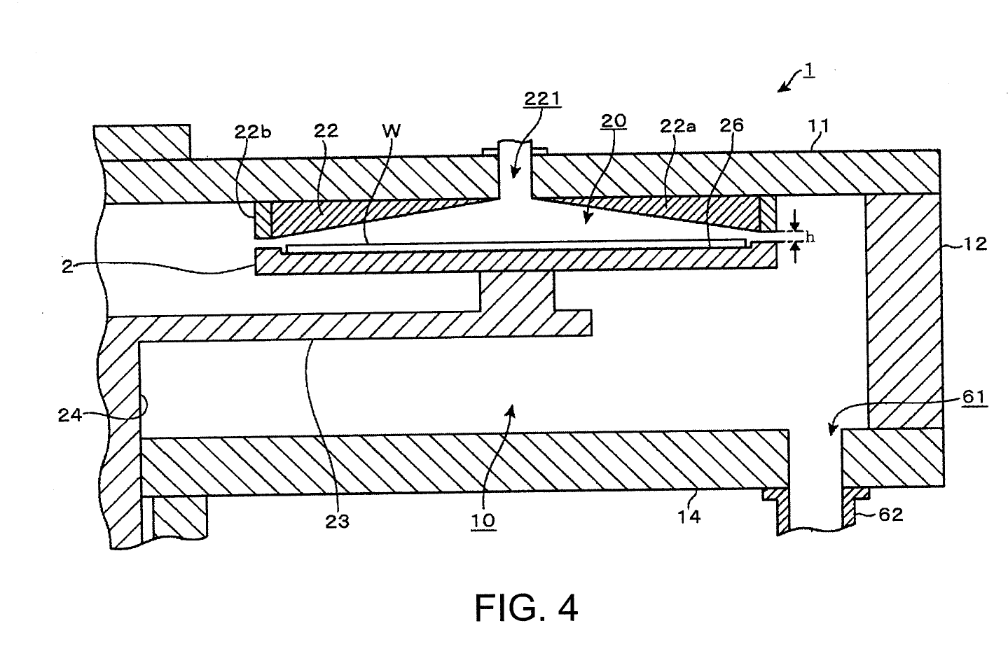

The tables 2 are disc-shaped plate members made of aluminum, nickel, or the like. Each table 2 is so made that it has a size larger than a wafer W with a diameter of e.g., 300 mm, which is a substrate to be processed by the film deposition system. As shown in FIG. 4, each table 2 has in its top a recess 26 that serves as a wafer-placing area (wafer-placing surface). Further, a stage heater 21, a means for heating a wafer W placed on the wafer-placing surface, composed of a resistance heater in sheet form, is embedded in each table 2. This allows a wafer W on the table 2 to be heated to a temperature of e.g., about 300° C. to 450° C. by electrical power supplied from a power source unit not shown in the figures. If necessary, an electrostatic chuck, not shown in the figures, may be placed in the table 2 in order to fix a wafer W placed on the table 2 by means of electrostatic attraction. In FIG. 3, a wafer W is depicted only on one table 2 for convenience's sake.

At the center of their undersides, the tables 2 are supported by supporting arms 23. The proximal ends of the supporting arms 23 are connected to the top of a support column 24 penetrating the center of the base plate 14 in the vertical direction. In this example, e.g., five supporting arms 23 extending nearly horizontally along the diameter of the vacuum vessel 1 to support the tables 2 with their tip end portions are arranged radially such that each two adjacent supporting arms 23 form almost the same angle in the circumferential direction. Consequently, the tables 2 supported by the tip end portions of the supporting arms 23 are arranged around the support column 24 in the direction of the circumference of the vacuum vessel 1 at equal spaces, as shown in FIGS. 2 and 3. The center of each table 2 comes on the circumference of a circle drawn round the support column 24.

At its bottom end, the support column 24 penetrating the base plate 14 is connected to a driving unit 51. This allows all the tables 2 connected to the support column 24 through the supporting arms 23 to be raised or lowered simultaneously. Namely, in this example, the supporting arms 23, the support column 24 and the driving unit 51 constitute a common elevating unit for all the tables 2. The driving unit 51 also serves as a rotating unit capable of rotating the support column 24 once around its vertical axis. This allows the tables supported by the supporting arms 23 to move circumferentially around the vertical axis of the support column 24. A sleeve 25 shown in FIG. 1 contains the support column 24 to maintain the airtightness of the vacuum vessel 1. A magnetic seal 18 airtightly isolates the atmosphere in the space surrounded by the support column 24 and the sleeve 25 from the atmosphere in the vacuum vessel 1.

As shown in FIGS. 2 and 3, the vacuum vessel 1 has, in its sidewall 12, a transportation opening 15 serving as a delivery opening through which delivery of a wafer W is made between a transporting arm 101 that is an external member for transporting a substrate, and each table 2. This transportation opening 15 is opened or closed by a gate valve not shown in the figures. The tables 2 move circumferentially in the vacuum vessel 1 when the support column 24 is rotated, and can successively stop at the position where the table 2 faces the transportation opening 15. At this position, a wafer W can be delivered to or from the table 2. The base plate 14 has, below this position for delivery, climbing pins 16, e.g., three, capable of rising from each wafer-placing surface through through-holes (not shown in the figures) in each table 2 to lift a wafer W from its back, thereby making the delivery of the wafer W between the transporting arm 101 and each table 2. The climbing pins 16 are supported by a climbing plate 53 at their ends. By raising or lowering this climbing plate 53 by means of a driving unit 52, it is possible to raise or lower the whole climbing pins 16. A bellows 17 covers the climbing pins 16 and connects the underside of the base plate 14 and the climbing plate 53; it serves to maintain the airtightness of the vacuum vessel 1.

To the underside of the top plate 11 of the vacuum vessel 1, top plate members 22, whose number are the same as the number of the tables 2, e.g., five, are fixed such that they are situated circumferentially around the center of the vacuum vessel 1, like the aforementioned tables 2, thereby constituting five pairs of the table 2 and the top plate member 22. When conducting film deposition, each top plate member 22 comes to face one table 2 to form a processing space 20. The tables 2 are movable in the circumferential direction around the support column 24, as mentioned previously, so that when the tables 2 are stopped at the predetermined positions (hereinafter referred to as “positions for processing”), the top plate members 22 face the corresponding tables 2.

As shown in FIG. 4, each top plate member 22 is composed of: a body 22a obtained by concaving an underside of a cylinder having a flat top from the edge of the cylinder toward the center of the cylinder so that the diameter of the resultant concavity continuously decreases as the depth of the concavity increases, where the concavity has a surface that forms a conical space whose transversal section area is spread from its apex (a trumpet-shaped concavity); and a sleeve 22b that is fixed to the outer periphery of the body 22a to surround it closely, that has a flat bottom end surface, and whose height is equal to that of the outer edge of the body 22a. The body 22a and the sleeve 22b are made of aluminum, for example. Since the above-described concavity has a circular opening whose diameter is a size larger than that of a wafer W to be placed on the table 2, it can cover the wafer W entirely. In FIG. 4, the distance between the bottom end of the top plate member 22 and the top of the table 2 is represented by “h”. The underside of the sleeve 22b is in the same height position as the bottom end of the top plate member 22, so that when the table 2 faces the top plate member 22, a gap with a height (width) of “h” is to be circumferentially formed between the bottom edge of the top plate member 22 and the table 2.

When the top plate member 22 having the above-described concavity and the discal table 2 are faced each other, a conical space is in this example formed between each pair of the table 2 and the top plate member 22. In the film deposition system according to this embodiment, a plurality of reactive gases supplied to the processing spaces 20 diffuse in them. The gases are adsorbed by the surface of the wafer W in each processing space 20 and cause expected reaction, whereby a film is deposited on the wafer W. The gases supplied to each processing space 20 flow into the vacuum vessel 1 through the gap formed between the table 2 and the top plate member 22 along the circumference of the processing space 20. The gaps in the film deposition system according to this embodiment correspond to exhaust openings for communicating the inside of the processing spaces 20 with the atmosphere in the vacuum vessel 1 situated outside the processing spaces 20 (corresponding to an exhaust space 10 that will be described later).

Each top plate member 22 having a conical concavity has a gas supply hole 221 at its apex. Through this gas supply hole 221, reactive gasses and a purge gas for purging the reactive gasses are supplied to the processing space 20.

Above the center of the top plate 11 is located a manifold unit 3 for supplying gases to the processing spaces 20. The manifold unit 3 has a vertical tubular passage member 31a constituting a gas supply passage 32, and a flat cylindrical member 31b with a larger diameter, the downstream end of the gas supply passage 32 being connected to the center of the top of the cylindrical member 31b. The cylindrical member 31b constitutes a gas diffusion chamber 33 for diffusing gasses introduced from the vertical gas supply passage 32 and supplying them to the five gas supply pipes 34.

All the gas supply pipes 34 have the same structure and extend radially from the sidewall of the cylindrical member 31b with a larger diameter toward the circumference at intervals of almost the same angle. The downstream ends of the gas supply pipes 34 are connected to the gas supply holes 221.

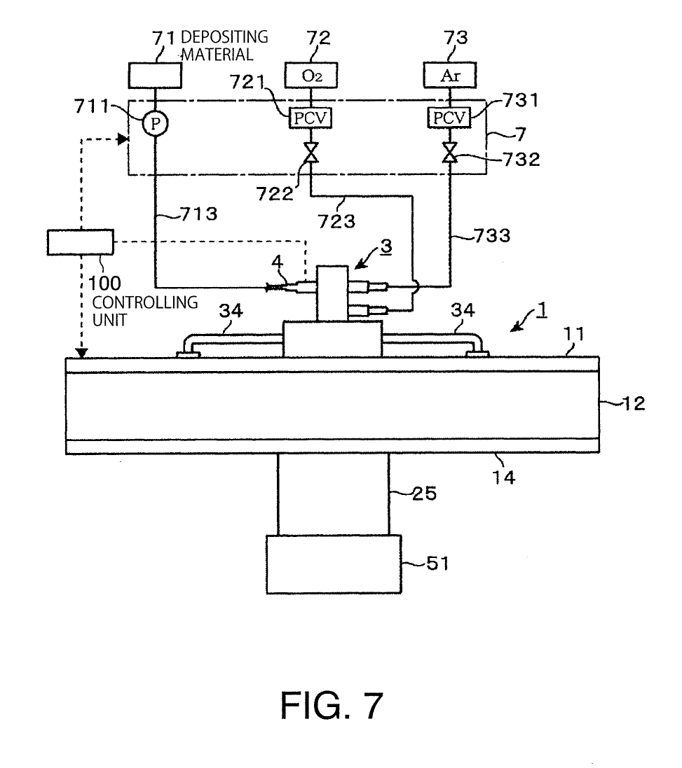

To the passage member 31a is attached an injector 4 for supplying a liquid depositing material to the gas supply passage 32 from a side of the passage 32. The liquid depositing material supplied from the injector 4 is vaporized to become a first reactive gas, a depositing material gas to be used for film deposition. Detailed description of the depositing material gas will be given later. To the injector 4 is connected a liquid depositing material supply pipe 713. The upstream end of the supply pipe 713 is connected to a depositing material gas supply source 71 in which a depositing material such as BTBAS is stored, via a pump 711 whose operation is controlled by a controlling unit 100 that will be described later (see FIG. 7). The depositing material gas supply source 71 is located e.g., above the injector 4 (see FIG. 7). This arrangement makes the passage between the depositing material gas supply source 71 and the injector 4 shorter. This prevents deterioration of the liquid depositing material, i.e., decrease in BTBAS concentration in the liquid depositing material that is brought about by volatilization or decomposition, achieving reduction in system operation costs. In order to prevent deterioration of the liquid depositing material effectively, the length of the supply pipe between the depositing material gas supply source 71 and the injector 4 is made e.g., 2 m or less.

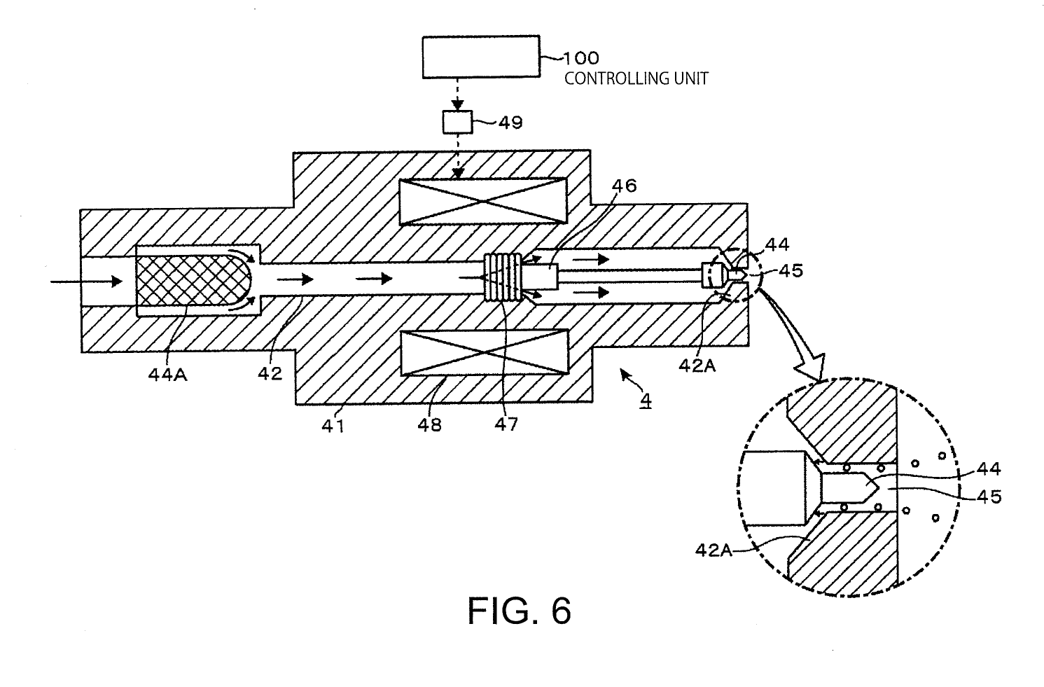

A conventionally known injector is used for this injector 4. The structure of a main part of the injector 4 will be described hereinafter with reference to FIG. 6, which is a longitudinal sectional view of the injector 4. The injector 4 has the main body 41; and the main body 41 has, in the longer direction, a supply passage 42 to which a liquid depositing material is supplied. The arrow in the figure shows the flow of the liquid depositing material. A liquid depositing material in the state of being pressurized by the pump 711 flows along the supply passage 42.

At its upstream end, the supply passage 42 is provided with a filter 44A for purifying the liquid depositing material. The supply passage 42 is reduced in its diameter on its downstream side and thus has a diameter-reduced part 42A; this part 42A has, at its downstream end, a discharge hole 45 that is opened or closed by a needle valve 44. The needle valve 44 is energized toward the downstream side by a return spring 47 via a plunger 46. This keeps the needle valve 44 in contact with the diameter-reduced part 42A to block the discharge hole 45. A solenoid 48 so placed that it surrounds the plunger 46 is connected to an electric current supply unit 49, and functions as an electromagnet when an electric current is supplied to it. Electric current supply to the solenoid 48 from the electric current supply unit 49 is controlled by a control signal from the controlling unit 100.

The plunger 46 is drawn to the upstream side of the supply passage 42 when an electric current is supplied to the solenoid 48 and an magnetic field is generated around it. Consequently, the needle valve 44 is drawn to the upstream side of the supply passage 42, and thus the discharge hole 45 is opened. The pressurized depositing material retained in the supply passage 42 is discharged from the discharge hole 45 toward the gas supply passage 32. Illustrated in the dashed line circle in FIG. 6 is an enlarged view of the upstream end of the injector 4, showing how the depositing material is discharged to the gas supply passage 32 through the discharge hole 45 that is open.

When the liquid depositing material is discharged from the injector 4, the gas supply passage 32 is in the sate of being depressurized. The liquid depositing material therefore causes vacuum boiling to become gas; the gas flows to the downstream side. When the generation of the magnetic field by the solenoid 48 is stopped, the plunger 46 is pressed back to the downstream side by the return spring 47, and the discharge hole 45 is blocked again by the needle valve 44. The flow rate of the first reactive gas produced in the gas supply passage 32 is regulated by controlling the pressure of the pump 711 and the time for which the discharge hole 45 is kept open. It should be noted that besides the above embodiment that a liquid depositing material is vaporized by supplying it from the injector 4 to the depressurized gas supply passage 32, the following embodiment can be adopted. That is to say, a vaporizer may be attached to the supply pipe 713; before being supplied to a flow space, a liquid depositing material is vaporized by the vaporizer, and the reactive gas produced in this manner is supplied to the gas supply passage 32.

As shown in FIG. 7, besides the supply pipe 713 for supplying a depositing material, other gas supply pipes 723, 733 for supplying various gases to the gas supply passage 32 are connected to the upper and the lower parts of the manifold unit 3, respectively. On the upstream side, the gas supply pipes 723, 733 are connected to gas supply sources 72, 73 for supplying different gases, respectively. In this example, the gas supply pipes 723, 733 are connected to the manifold unit 3 such that their gases can be supplied to the gas supply passage 32 from a direction different from the one from which the liquid depositing material is supplied to the gas supply passage 32 from the injector 4.

According to the film deposition system of this embodiment, it is possible to deposit thin films containing elements, e.g., elements in the third group in the periodic table such as Al and Si, elements in the fourth group in the periodic table such as Ti, Cr, Mn, Fe, Co, Ni, Cu, Zn and Ge, elements in the fifth group in the periodic table such as Zr, Mo, Ru, Rh, Pd and Ag, and elements in the sixth group in the periodic table such as Ba, Hf, Ta, W, Re, Ir and Pt. For example, an organometallic or inorganic metallic compound of any of the above metal elements is used, in the form of a reactive gas (depositing material gas), as a metallic depositing material to be adsorbed by a wafer W surface, for example. Specific examples of the metallic depositing material include, besides the above-described BTBAS, DCS (dichlorosilane), HCD (hexadichlorosilane), TMA (trimethyl aluminum), and 3DMAS (tris-dimethylaminosilane).

In order to obtain a desired film by allowing the depositing material gases adsorbed by the wafer W surface to react with each other, it is possible to use various reactions including oxidation using O₂, O₃ or H₂O, reduction using H₂, an organic acid such as HCOOH or CH₃COOH, or an alcohol such as CH₃OH or C₂H₅OH, carbonization using CH₄, C₂H₆, C₂H₄ or C₂H₂, or nitrification using NH₃, NH₂NH₂ or N₂. This embodiment will be explained by referring to the example in which SiO₂ film is deposited by means of oxidation using, as the depositing material gas, a BTBAS gas exemplified in the background art, and an oxygen gas.

Connected to the oxygen gas supply source 72, the oxygen gas supply pipe 723 can carry the oxygen gas, as a second reactive gas, to the gas supply passage 32. The purge gas supply pipe 733 is connected to the purge gas supply source 73 to allow an argon gas, as a purge gas, to be supplied to the gas supply passage 32. In the gas supply pipe 723 for carrying the oxygen gas to the gas supply passage 32 are placed a pressure control valve 721 of e.g., diaphragm type and an on-off valve 722 composed of a magnetic valve using e.g., disc-type plungers. In the gas supply pipe 733 for carrying the argon gas to the gas supply passage 32 are placed a pressure control valve 731 of e.g., diaphragm type and an on-off valve 732 composed of a magnetic valve using e.g., disc-type plungers. This allows various gasses at a constant pressure to be supplied at a high flow rate and a high speed of response.

Constituting a gas supply controlling unit 7 in the film deposition system, the pump 711 connected to the gas supply sources 71, 72, 73, the pressure control valves 721, 731 and the on-off valves 722, 732 can control the timing of each gas supply, and so on, based on instructions of the controlling unit 100 that will be described later. Further, in this example, among the above-described components, the depositing material gas supply source 71, the pump 711, the depositing material gas supply pipe 713, the injector 4, the manifold unit 3, and the gas supply pipe 34 constitute a first-reactive-gas supply unit; the oxygen gas supply source 72, the pressure control valve 721, the on-off valve 722, the oxygen gas supply pipe 723, the manifold unit 3, and the gas supply pipe 34 constitute a second-reactive-gas supply unit; and the purge gas supply source 73, the pressure control valve 731, the on-off valve 732, the purge gas supply pipe 733, the manifold unit 3, and the gas supply pipe 34 constitute a purge gas supply unit.

On top of the passage member 31a is located a remote plasma supply unit 54 for supplying a plasma gas to the processing spaces 20. For maintenance of the system, an NF₃ gas is supplied to the remote plasma supply unit 54 while conducting evacuation as will be described later; the remote plasma supply unit 54 makes the gas into the state of plasma. When supplied to the processing spaces 20, the generated plasma separates (removes) the deposits from surfaces of the walls of the processing spaces 20; the separated deposits are carried with the exhaust gas flows created in the processing spaces 20 and are removed therefrom. Instead of the remote plasma supply unit 54, the injector 4 may be placed above the passage member 31a, and the liquid depositing material may be supplied from the injector 4 along the gas supply passage 32 in the passage member 31a.

Turning now to the explanation of the vacuum vessel 1, e.g., the base plate 14 has, at the opposite of the transportation opening 15 relative to the support column 24, a common exhaust hole 61 through which the reactive gases and the purge gas are exhausted. To this exhaust hole 61 is connected an exhaust pipe 62, and the exhaust pipe 62 is connected to a vacuum pump 64, as a means of evacuation (creating a vacuum), via a pressure-adjusting unit 63 for controlling the pressure in the vacuum vessel 1. In the vacuum vessel 1, five pairs of the table 2 and the top plate member 22 that constitute the processing spaces 20 in which the film deposition is conducted are arranged as mentioned previously. The gases flowing out of these five processing spaces 20 pass through the vacuum vessel 1 and are exhausted from the common exhaust hole 61. Namely, it can be said that the vacuum vessel 1 constitutes a reactive-gas exhaust space 10. In other words, the film deposition system according to this embodiment can be said to have the structure that a plurality of processing spaces 20 are arranged in a common exhaust space 10.

The film deposition system having the above-described structure has the controlling unit 100 for controlling the operation for each gas supply from the gas supply sources 71, 72, 73, the operation for rotating, raising and lowering the tables 2, the operation for exhausting the vacuum vessel 1 with the vacuum pump 64, the operation for heating with the stage heaters 21, and so forth. The controlling unit 100 is composed of e.g., a computer having a CPU and a storage unit, not shown in the figures. In this storage unit is stored a program containing groups of steps (commands) for controlling the film deposition system, required for film deposition on wafers W; for example, steps for controlling the timing of the start or stoppage and the flow rate of each gas supply from the gas supply sources 71, 72, 73; steps for controlling the degree of vacuum in the vacuum vessel 1; steps for controlling the operations for raising, lowering, and rotating the tables 2; steps for controlling the temperature of the stage heaters 21; and so on. Usually, this program is stored in a storage medium such as a hard disc, a compact disc, a magnet-optical disc, or a memory card and is installed in a computer from the medium.

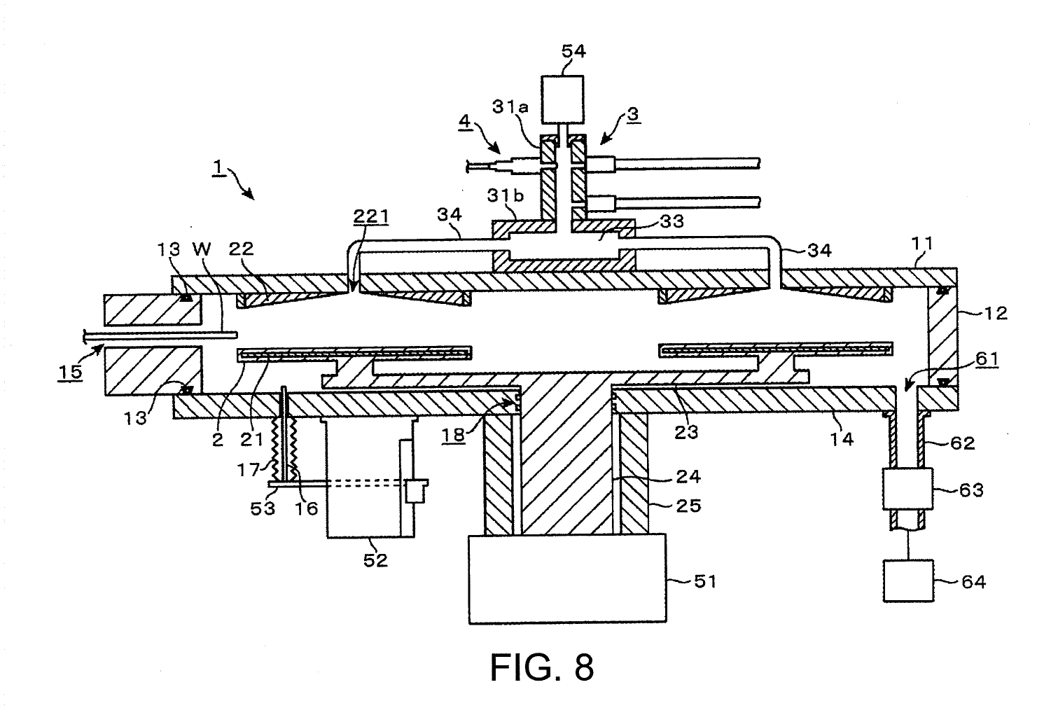

Operation of the film deposition system according to this embodiment will be explained hereinafter. As shown in FIG. 8, a gate valve, not shown in the figure, is first opened, with the tables 2 lowered to the wafer W delivery position, whereby the transportation opening 15 is opened, and the external transporting arm 101, carrying a wafer W, comes in the vacuum vessel 1 through the transportation opening 15. At this time, the support column 24 is rotated so that one of the tables 2, on which the transporting arm 101 will place a wafer W for the next time, has been brought to the position in front of the transportation opening 15 in the vacuum vessel 1 (wafer W delivery position) and is waiting for receiving a wafer W. The climbing pins 16 are raised through the through-holes, not shown in the figure, made in each table 2; a wafer W is delivered from the transporting arm 101 to the climbing pins 16; and the climbing pins 16 are lowered under the table 2 after the transporting arm 101 has withdrawn from the vacuum vessel 1, whereby the wafer W is placed in the recess 26 as a wafer-placing surface in the table 2. The wafer W is fixed by means of suction caused by an electrostatic chuck not shown in the figure.

After the transportation of wafers W to the five tables 2 by repeating the above operation for placing a wafer W on the table 2 has been completed, the tables 2 are moved to the processing positions and then stopped, with the tables 2 facing the top plate members 22. Since the tables 2 have been heated to a temperature of e.g., 300 to 450° C. by the stage heaters 21 beforehand, the wafers W are heated when placed on the tables 2. The tables 2 that have been lowered to the wafer W delivery position are raised and then stopped at the height position selected according to e.g., the recipe for the film deposition.

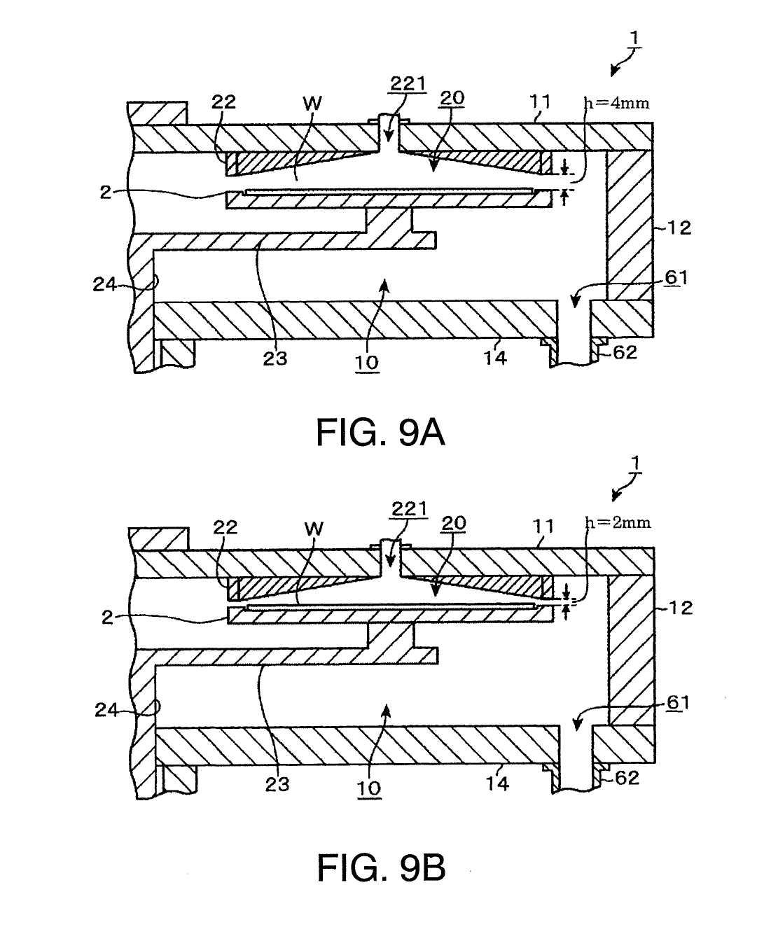

In the film deposition system according to this embodiment, the width of the gap (the height of the gap) between the table 2 and the top plate member 22 can be varied in the range of e.g., “h=1 mm-6 mm” by adjusting the height position at which the table 2 is stopped. For example, FIG. 9A shows a case where the gap width is “h=4 mm”, and FIG. 9B a case where the gap width is “h=2 mm”.

After facing the tables 2 and the top plate members 22 each other and adjusting the gap widths in the above-described manner, the vacuum vessel 1 is made airtight by closing the transportation opening 15. After this, the vacuum vessel 1 is evacuated by operating the vacuum pump 64. After the vacuum vessel 1 has been evacuated to the predetermined pressure, e.g., 13.3 Pa (0.1 Torr), and the wafers W have been heated to a temperature in the above-described range, e.g., 350° C., the film deposition operation is started.

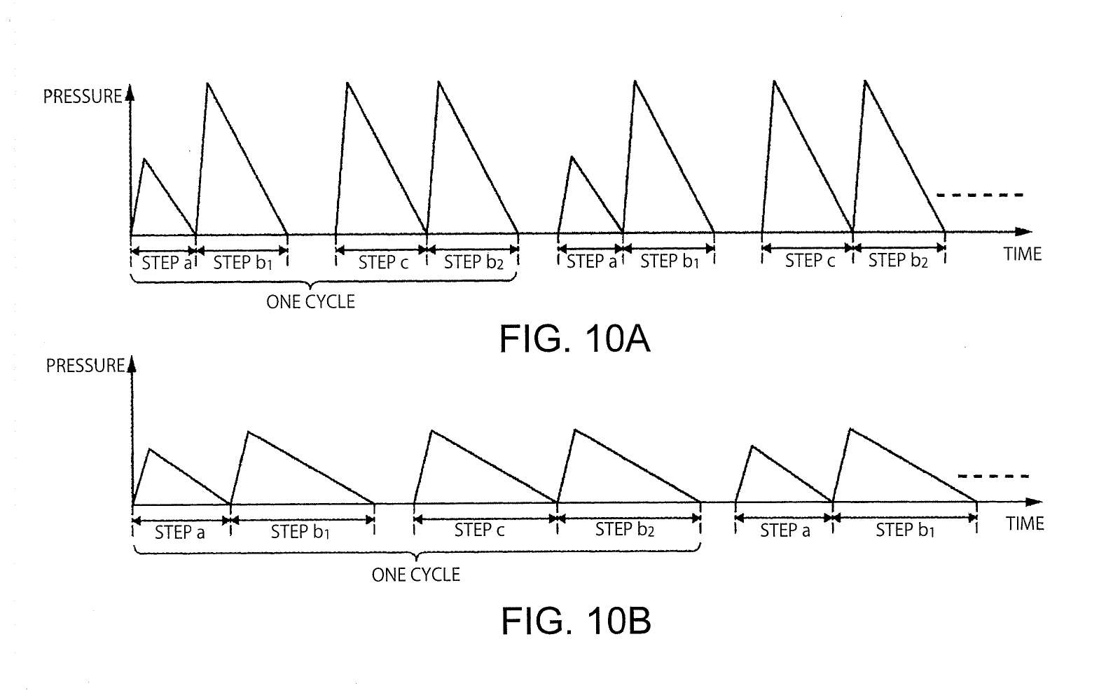

In a so-called ALD process using the film deposition system according to this embodiment, the film deposition operation is conducted in accordance with e.g., a sequence of gas supply shown in FIG. 10A or FIG. 10B. FIG. 10A is a diagram showing a sequence of gas supply in the case where the width of the gap between the table 2 and the top plate member 22 is “h=4 mm” (corresponding to the case shown in FIG. 9A). FIG. 10B is a diagram showing a sequence of gas supply in the case where the width of the gap between the table 2 and the top plate member 22 is “h=2 mm” (corresponding to the case shown in FIG. 9B). These diagrams plot the time as the abscissa and the pressure in the processing spaces 20 as the ordinate.

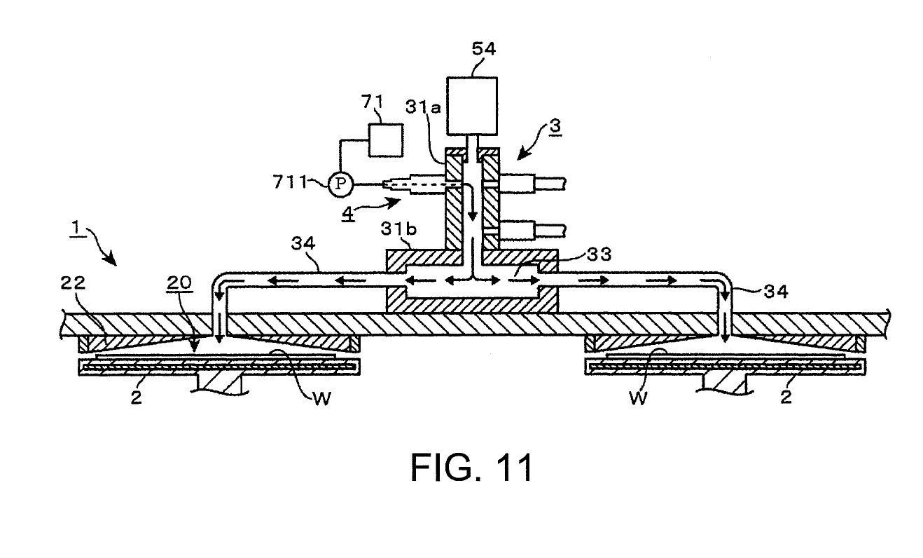

For example, referring to the case shown in FIG. 10A (h=4 mm), the step of supplying the depositing material gas (first reactive gas BTBAS) to the processing spaces 20, and allowing wafers W on the tables 2 to adsorb the gas (the step of allowing wafers W to adsorb the depositing material gas: hereinafter abbreviated to the adsorption step, “step a” in FIG. 10A), is first performed. In this step, a liquid starting material for BTBAS, stored in the depositing material gas supply source 71, is discharged to the depressurized gas supply passage 32 through the discharge hole 45 in the injector 4, while the discharge hole 45 is kept open for e.g., 1 msec; vacuum boiling occurs and the starting material becomes BTBAS gas as the first reactive gas. The BTBAS gas is supplied to the gas diffusion chamber 33 situated on the downstream side, as indicated by an arrow in FIG. 11; it diffuses in the gas diffusion chamber 33 and flows toward the downstream side.

This depositing material gas produced by vaporization is introduced into the processing spaces 20 through the gas supply holes 221. This increases the pressure in the processing spaces 20 to e.g., 133.32 Pa (1 Torr), as shown in “step a” in FIG. 10A. On the other hand, the processing spaces are arranged in the exhaust space 10, as mentioned previously, so that the depositing material gas supplied to the processing spaces 20 flows toward the exhaust space 10 because the pressure in the exhaust space 10 is lower than the pressure in the processing spaces 20, i.e., enters the exhaust space 10 through the gaps between the tables 2 and the top plate members 22.

Consequently, the depositing material gas is supplied to the conical processing spaces 20 from their apexes, i.e., through the gas supply holes 221 situated above the centers of the wafers W, and, while spreading in the processing spaces 20, it flows across the wafer W surfaces toward the gaps. In this course, the depositing material gas is adsorbed by the wafer W surfaces to form thereon BTBAS molecular layers. As the depositing material gas supplied intermittently is exhausted from the processing spaces 20 toward the exhaust space 10, the pressure in the processing spaces 20 decreases, as shown in “step a” in FIG. 10A.

Subsequently, the step of purging the depositing material gas remaining in the processing spaces 20 (“step b1” shown in FIG. 10A) is performed when the pressure in the processing spaces 20 becomes almost the same as that before the introduction of the depositing material gas (e.g., after a predetermined time has passed since the supply of the depositing material gas was started). In this step, the pressure control valve 731 situated on the downstream side of the purge gas supply source 73 is adjusted such that the secondary pressure on the outlet side remains constant at 0.1 MPa, and the on-off valve 732 is “off” with this pressure exerted to the inlet side. The on-off valve 732 is kept “on” for a period of e.g., 100 ms after starting “step b1”. By doing so, the purge gas is supplied to the processing spaces 20 via the manifold unit 3 at the rate determined by: the balance between the pressures in the portions of the passage before and after the on-off valve 732; and the time for which the on-off valve 732 was kept “on”.

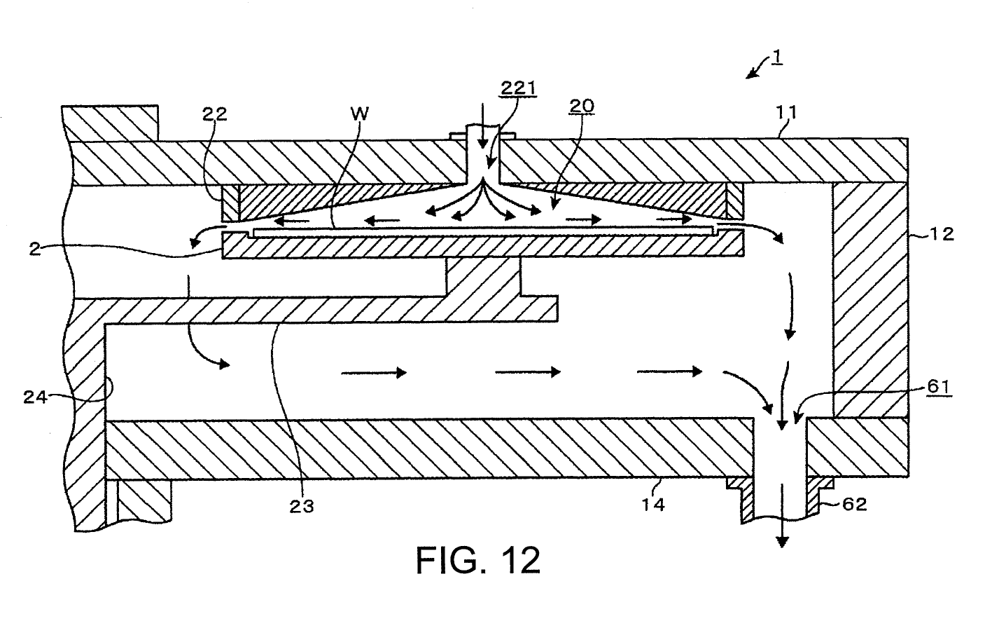

Consequently, like the depositing material gas, the purge gas flows over the wafer W surfaces while spreading in the conical processing spaces 20, and is exhausted, together with the depositing material gas remaining in the processing spaces 20, toward the exhaust space 10 through the gaps between the tables 2 and the top plate members 22, as shown in FIG. 12. In this step, the pressure in the processing spaces 20 increases to e.g., 666.7 Pa (5 Torr), as shown in “step b1” in FIG. 10A, which is dependent on the amount of the purge gas that was supplied by opening or closing the on-off valve 732, and then decreases as the purge gas is exhausted toward the exhaust space 10.

After the depositing material gas remaining in the processing spaces 20 has been exhausted together with the purge gas (e.g., after a predetermined time has passed since the supply of the purge gas was started), the step of supplying the oxygen gas, second reactive gas, to the processing spaces 20 is performed in order to oxidize the depositing material gas adsorbed by the wafers W (hereinafter referred to as the “oxidation step”, “step c” in FIG. 10A). For example, like the pressure control valve 731 for the purge gas, the pressure control valve 721 situated on the downstream side of the oxygen gas supply source 72 is adjusted such that it can keep the secondary pressure on the outlet side constant at 0.1 MPa, and the on-off valve 722 is “off” with this pressure exerted to the inlet side. The on-off valve 722 is kept open for e.g., 100 ms after starting “step c”. By doing so, the oxygen gas is supplied to the processing spaces 20 via the manifold unit 3 at the rate determined by the balance between the pressures in the portions of the passage before and after the on-off valve 722; and the time for which the on-off valve 722 was kept open.

Like in the above-described gas supply steps, the oxygen gas flows over the wafer W surfaces while spreading in the conical processing spaces 20, as shown in FIG. 12, to oxidize the depositing material gas adsorbed by the wafer W surfaces, whereby SiO₂ molecular layers are formed on the wafer W surfaces. In this step, the pressure in the processing spaces 20 increases to e.g., 666.7 Pa (5 Torr), which is dependent on the amount of the oxygen gas that was supplied to the processing spaces 20 by opening or closing the on-off valve 722, and then decreases as the oxygen gas is exhausted toward the exhaust space 10, as shown in “step c” in FIG. 10A.

Subsequently, the step of purging the oxygen gas remaining in the processing spaces 20 (“step b2” shown in FIG. 10A) is performed in the same manner as in the above-described “step b1” when the pressure in the processing spaces 20 becomes almost the same as that before the introduction of the oxygen gas (e.g., after a predetermined time has passed since the supply of the oxygen gas was started). As shown in FIG. 10A, a cycle of the above-described four steps is repeated predetermined times, e.g., 125 times, to form a multi-layered SiO₂ molecular layer, whereby deposition of a thin film with a total thickness of e.g., 10 nm is completed.

FIG. 10A and also FIG. 10B that will be described later diagrammatically show the patterns of pressure in the processing spaces 20 in the respective steps, and do not show the pressure in the processing spaces 20 precisely (strictly).

After completion of the film deposition, the gas supply is stopped, and the tables 2 having thereon the wafers W are lowered to the height of the transportation opening 15, and the pressure in the vacuum vessel 1 is returned to the one before evacuation. After this, following the course reverse to that of transportation of the wafers W to the vacuum vessel 1, the wafers W are carried out of the vacuum vessel 1 by the external transporting arm 101, whereby a series of operations for the film deposition is completed.

In the film deposition system according to this embodiment in which the above-described operations are conducted to deposit thin films, the reactive gases are supplied to the five processing spaces 20 from the common manifold unit 3, and are exhausted from the processing spaces 20 toward the common exhaust space 10. There is therefore the possibility that a slight difference in the supply of each reactive gas may be produced among the five processing spaces 20. The film deposition system, however, employs an ALD process that uses adsorption of the reactive gases by the wafer W surfaces, so that even if the supplies of each reactive gas to the processing spaces 20 are slightly different from one another, it is possible to form, on the wafer W surfaces, films that are uniform in film qualities such as film thickness among the wafers W as long as each reactive gas is supplied to the wafer W surfaces in an amount large enough to form molecular layers.

Further, in the film deposition system according to this embodiment, the gaps between the tables 2 and the top plate members 22 can be varied in the range of “h=1 mm-6 mm”, as mentioned previously. The above-described FIG. 10A shows a sequence of gas supply when h=4 mm (FIG. 9A). Now, the operation of the film deposition system when the gaps between the tables 2 and the top plate members 22 are decreased to “h=2 mm”, as shown in FIG. 9B, and the effect of this decrease on the sequence of gas supply will be described hereinafter.

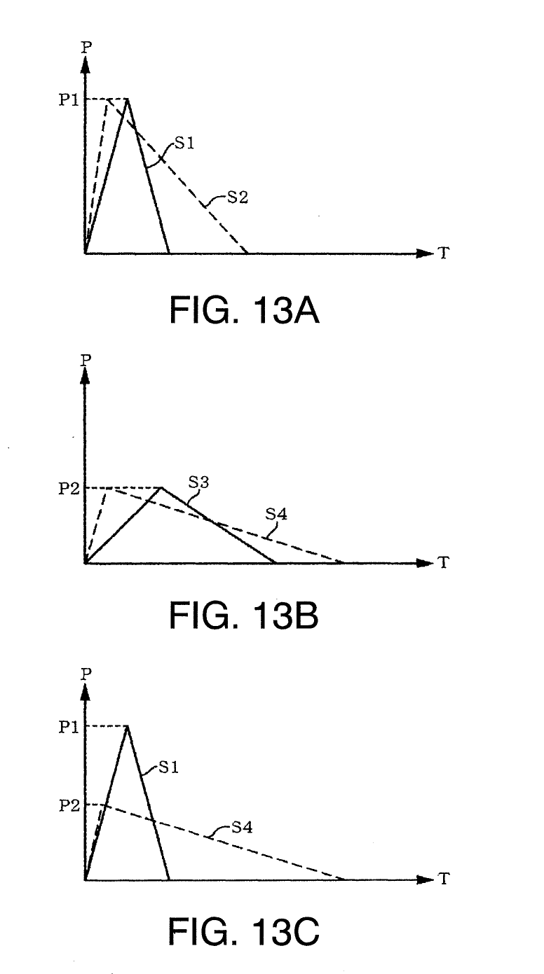

After controlling the supply flow rate of the depositing material gas from the injector 4 so that the pressure in the processing spaces 20 remains constant (e.g., pressure P1), if the gaps between the tables 2 and the top plate members 22 are narrowed, the pressure loss at the time when the gas passes through the gaps increases. Owing to this, the rate of exhaustion of the reactive gas(es) from the processing spaces 20 to the exhaust space 10 decreases, and the residence time of the reactive gas in the processing spaces 20 increases. The change in pressure in the processing spaces 20 in this course is diagrammatically shown in FIG. 13A. As shown in this figure, before the gaps are narrowed, the pressure in the processing spaces 20 drops sharply in a short time, as indicated by a solid line S1, whereas the pressure smoothly decreases after the gaps have been narrowed, as indicated by a dotted line S2. FIGS. 13A to 13C plot the time as the abscissa and the pressure in the processing spaces 20 as the ordinate.

Next, after controlling the supply flow rate of the depositing material gas from the injector 4 so that the pressure in the processing spaces 20 becomes lower than the above pressure P1 (e.g., pressure P2), if the gaps between the tables 2 and the top plate members 22 are changed, the change in the pressure in the processing spaces 20 before the gaps are narrowed and the change in the pressure after the gaps have been narrowed are as diagrammatically shown in FIG. 13B. Namely, although the entire change is smoother than in FIG. 13A described above, the pressure decreases over a relatively short period of time, as indicated by a solid line S3, before the gaps are narrowed, and it decreases over a relatively long period of time, as indicated by a dotted line S4, after the gaps have been narrowed.

Thus, in the film deposition system according to this embodiment, it is possible to control at least either the pressure in the processing spaces 20 or the residence time of the depositing material gas in the processing spaces 20 by adjusting both the widths of the gaps between the tables 2 and the top plate members 22 and the supply flow rate of the depositing material gas from the injector 4, in order to provide a supply pattern which the depositing material gas supply time is short and thus a relatively large amount of the depositing material gas is required (corresponding to the solid line S1 in FIG. 13C), another supply pattern which the depositing material gas supply time is long and thus the depositing material gas is less consumed (corresponding to the dotted line S4 in FIG. 13C), and so forth. Namely, it is possible to vary the pattern of depositing material gas supply freely.

In the sequence of gas supply shown in FIG. 10B, the gap width is fixed to h=2 mm, and the supply of the depositing material gas is so determined that the area of the time-pressure triangle in “step a” is equal to that of the triangle in “step a” in FIG. 10A.

The reason why the supply flow rate of the depositing material gas is determined so that the areas of the above two triangles in FIGS. 10A and 10B become the same is that: the film qualities, such as film thickness, are considered to be dependent on the number of collisions of the depositing material gas molecules with a wafer W surface, since the ALD process is a film deposition technique that makes use of adsorption of the depositing material gas by the wafer W surface. The frequency of collisions of the depositing material gas molecules with the wafer W surface increases in proportion to the pressure in the processing spaces 20, i.e., the concentration of the depositing material gas supplied to the processing spaces 20, and the total number of collisions in the period of the film deposition is equal to a value obtained by time-integrating the frequency of collisions. It is therefore considered that it is possible to keep the same the film qualities before the gap width is changed and those after the gap width has been changed by making the same the integrated values, i.e., the areas of the triangles. Also in the sequence of gas supply shown in FIG. 10B, the supplies of the gases shown in steps c, b1 and b2 are determined on the basis of the above conception.

Here, it is possible to control the supply flow rate of each gas by changing e.g., the time for which the injector 4 and the on-off valves 722, 732 are kept open. The area of the triangle in the sequence of gas supply before the gap width is changed (in this example, the sequence shown in FIG. 10A, where h=4 mm), and so forth are determined by grasping beforehand e.g., the supply flow rates of the gases with which good film qualities can be obtained, by means of preliminary experiments, etc. The method for determining the sequence of gas supply shown in FIG. 10B, when the gap width is changed, is not limited to the above-described one. A sequence of gas supply suited to a certain gap width may be determined by carrying out preliminary experiments in which the gap width is varied and obtaining from the experimental results the supply flow rate of each gas optimal to each gap width.

After obtaining the sequence of gas supply suited to each gap width by the above-exemplified method, it is advisable to compare the effect of change in film deposition time brought about by the change in the gap width, i.e., the effect of change in throughput, on profit, with the effect of change in consumption of the gases on costs, and then to determine the suitable gap width so that the balance of these two effects reaches a maximum. This determination of the gap between the table 2 and the top plate member 22 can be made before operating the film deposition system, or before changing the process conditions, e.g., the depositing material gas to be supplied.

The film deposition system according to this embodiment has the following effects. The film deposition system, in which the depositing material gas (first reactive gas) and the oxygen gas (second reactive gas) are alternately supplied to wafers W to form thereon thin films by means of so-called ALD (or MLD), has the following structure: the table 2 having a wafer-placing area and the top plate member 22 are so placed that they face each other to form the processing space 20 between them; the plurality of pairs of the table 2 and the top plate member 22 are arranged in the vacuum vessel 1, which is the common exhaust space 10; and the processing spaces 20 are evacuated through the gaps between the tables 2 and the top plate members 22. This film deposition system can therefore have a smaller (total) volume of the processing spaces as compared with a conventional system obtained by preparing a large rotatable table, on which a plurality of wafers W can be placed, and forming a common processing space above the rotatable table. Moreover, in the film deposition system of this embodiment, the reactive gases do not flow in those areas that are not concerned with the film deposition, such as spaces between the wafers W, so that the film deposition can be done with decreased supplies of the reactive gases. It is therefore possible to conduct the film deposition at a lower cost. Further, since the total volume of the processing spaces 20 is small, the time required to supply the reactive gases to the processing spaces 20 and also the time to exhaust the reactive gases are less than ever, which leads to decrease in total film deposition time. Namely, that the total volume of the processing spaces 20 is small can also make the film deposition system improved in throughput.

Further, in the film deposition system of this embodiment, the reactive gases are supplied to stationary wafers W, so that unlike a film deposition system of such a type as is described in the background art, in which a table on which a plurality of wafers W are placed is rotated, unnecessary consumption of the reactive gasses, which may be caused because the rate of movement of those portions of the wafers that are situated on the center side of the table is different from that of those portions of the wafers that are situated on the edge side of the table, never occurs.

The film deposition system according to this embodiment, comprising the elevating mechanism (the supporting arms 23, the support column 24, the driving unit 51) for raising and lowering the tables 2 that form the processing spaces 20, has the following effects. By placing wafers W in the processing spaces 20 formed between the concave surfaces of the top plate members 22 and the tables 2, and adjusting the widths of the gaps between these members 2, 22, it is possible to control the pressure in the processing spaces 20 and the residence times of the respective reactive gases in the processing spaces 20. The conditions required for film deposition on the wafer W surfaces can therefore be created in the narrow processing spaces 20, as desired. For this reason, the film deposition system of this embodiment requires smaller amounts of the reactive gases to deposit films as compared with a conventional film deposition system of the type described in the background art, in which a gas shower head with a flat gas discharge face is placed in a vacuum vessel in parallel with a table.

Furthermore, by making use of the advantage that the widths (heights) of the gaps between the tables 2 and the top plate members 22 are changeable, it is possible to select the gap width optimal to the desired process to be used by comparing the effect of increase in the gap width on decrease in the film deposition time, i.e., on improvement in throughput, and the effect of decrease in the gap width on reduction of the depositing material gas consumption. The film deposition system therefore can be used much more flexibly with a variety of processes.

In the sequences of gas supply in the above-described embodiment, shown in FIG. 10A and FIG. 10B, the widths (heights) between the tables 2 and the top plate members 22 are kept constant throughout the adsorption step, the purge step, and the oxidation step. Practical operations of the film deposition system according to this embodiment, however, are not limited to this. For example, by making the gap width (height) in the adsorption step different from the one in the oxidation step, it is possible to change the pressure in the processing spaces 20 and the residence time of the reactive gas in the processing spaces 20 based on each reactive gas to be supplied to the processing spaces 20 in each step. This makes it possible to deposit films of better quality.

The method for changing the gap width is not limited to the above-described one in which the gap width is changed by raising or lowering the tables 2. For example, the top plate members 22 may be structured so that they can descend from the top plate of the vacuum vessel 1, and the gap width may be changed by raising or lowering the top plate members 22, or both the tables 2 and the top plate members 22.

Next, the manifold unit 3 in this embodiment has the following effects. Each gas supplied from the processing gas supply mechanism composed of the injector 4 and the gas supply pipes 723, 733 flows in the gas diffusion chamber 33 via the common gas supply passage 32; the gas diffuses in the gas diffusion chamber 33 and is supplied to the processing spaces 20 via the gas supply pipe 34. For this reason, the number of components needed to compose the processing gas supply mechanism is smaller as compared with the case where the processing spaces 20 are individually provided with the processing gas supply mechanisms. The gas supply system thus has a simplified structure, which prevents the film deposition system from becoming large in size and getting complicated. The film deposition system can therefore be produced at a lower cost.

Further, the processing spaces 20 to which the gases are supplied are composed of the top plate members 22 and the tables 2, and the gases are exhausted through the gaps between these members 22, 2. The processing spaces 20 therefore have a smaller total volume as compared with the case where a large rotatable table on which a plurality of substrates can be placed is prepared and a common processing space is formed above the rotatable table. Owing to this, the reactive gases do not flow in those areas that are not concerned with the film deposition, such as spaces between the substrates, so that it is possible to conduct the film deposition with decreased supplies of the reactive gases. Moreover, since the gases are supplied to the processing spaces 20 from the gas supply sources via the common gas supply passage 32 and the common gas diffusion chamber 33, the flow rate and the concentration of each gas to be supplied to the processing spaces 20 do not fluctuate. It is therefore possible to prevent the films deposited on the wafer W surfaces in the processing spaces 20 from having varied film quality or thickness.

Furthermore, since the gas diffusion chamber 33 is located right above the vacuum vessel 1 containing the processing spaces 20, the gas passage between the gas diffusion chamber 33 and the processing spaces 20 can have a shorter length. The shorter gas passage makes it possible to prevent the BTBAS gas from being reliquefied before it reaches the processing spaces 20, and also makes it easy to supply a large amount of gas to the processing spaces 20 in a short time. This leads to decrease in film deposition time, resulting in improvement in throughput. The length of the passage between the gas diffusion chamber 33 and each processing space 20 is e.g., 0.3 m to 1.0 m.

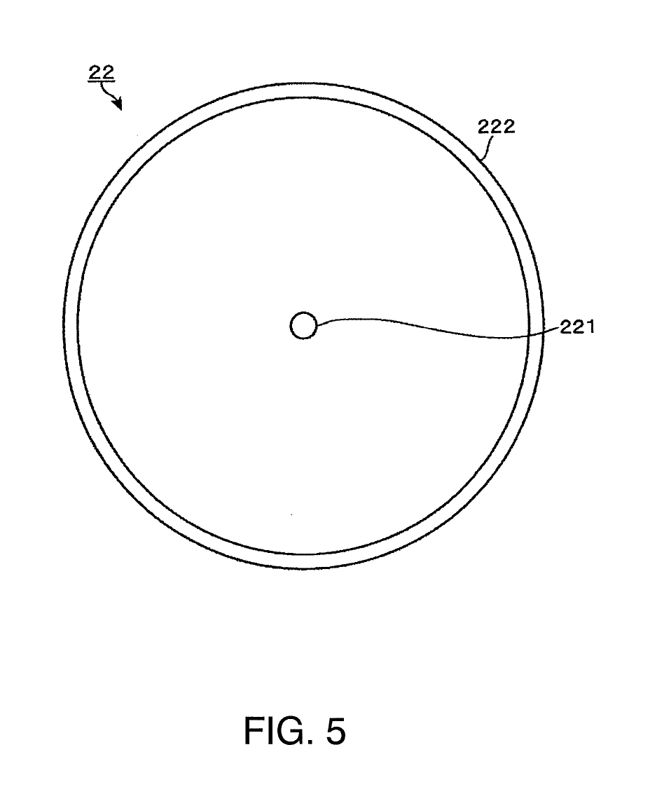

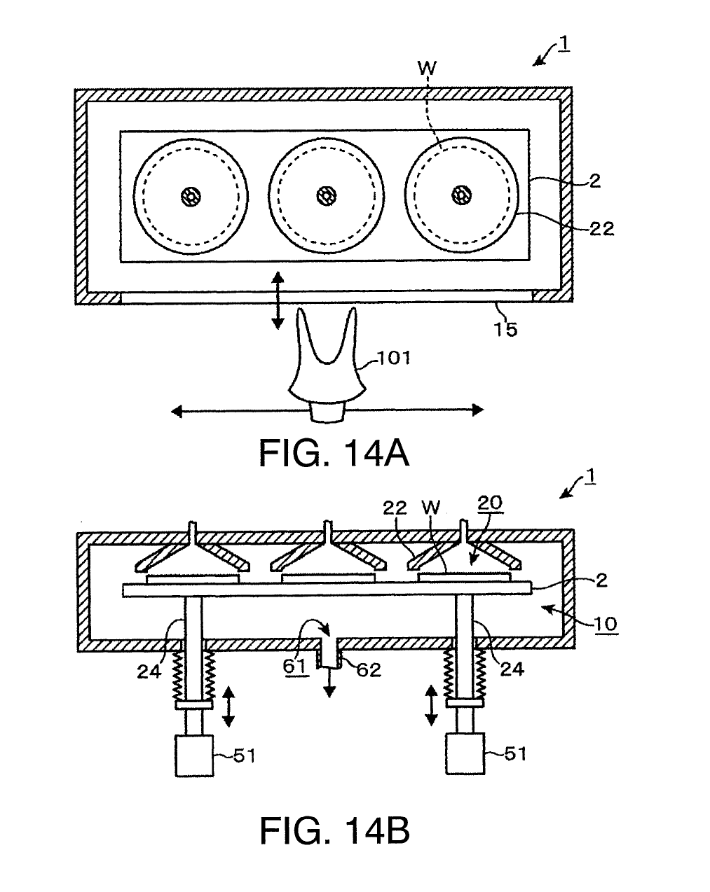

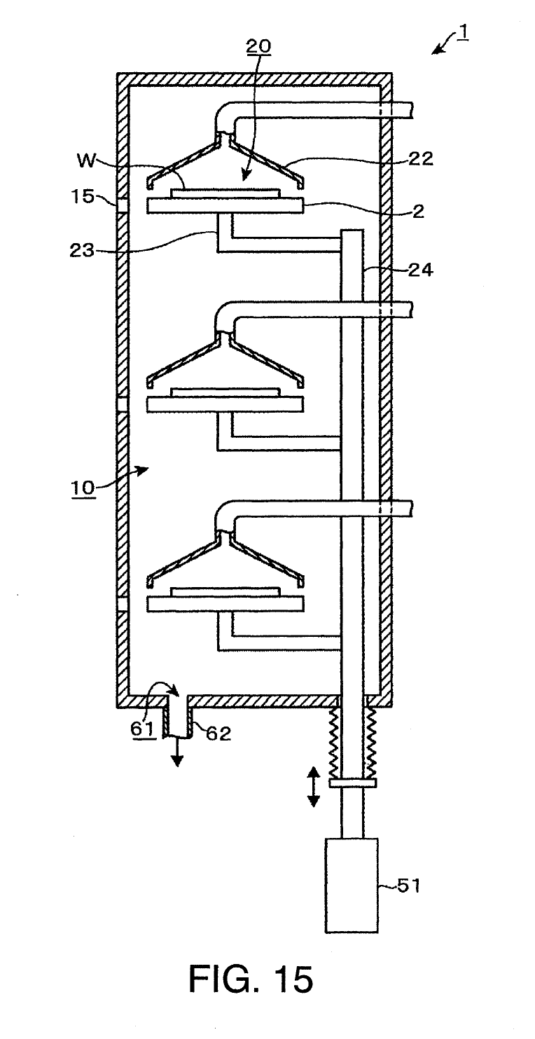

The film deposition system according to this invention is not limited to the aforementioned embodiment in which a plurality of pairs of the table 2 and the top plate member 22 are circumferentially arranged in the vacuum vessel 1 that is in the shape of a flat cylinder, as shown in FIGS. 1 to 7 (the embodiment in which the tables 2 are arranged on the circumference of a circle concentric with the vacuum vessel 1). For example, like a film deposition system shown in FIG. 14A and FIG. 14B, a plurality of wafer-placing areas may be formed in a row in the horizontal direction on a long and narrow rectangular table 2, and top plate members 22 may be placed so that they face the wafer-placing areas; these members 2, 22 may be placed in a vacuum vessel 1 that is an exhaust space 10 having a common exhaust hole 61. Alternatively, like a film deposition system shown in FIG. 15, a plurality of pairs of a table 2 and a top plate member 22 facing the table 2 may be arranged vertically and may be placed in a vacuum vessel 1, which forms an exhaust space 10. In the drawings, the same reference numerals designate the same or corresponding parts throughout the film deposition systems described in this specification.

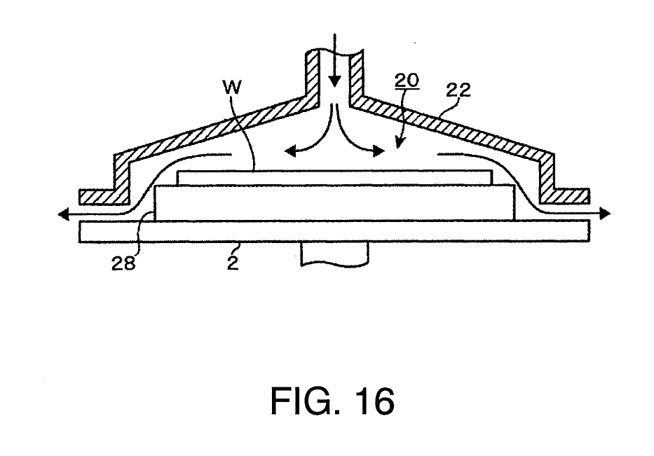

Further, the gap between the table 2 and the top plate member 22 is not limited to the gap between the top of the table 2 and the bottom end of the top plate member 22, described with reference to FIG. 4, and the following structure may also be adopted. For example, a table 2 having a raised (convex) wafer-placing area on its surface may be fit into a concavity in a top plate member 22 to form a processing space 20, as shown in FIG. 16, and the gasses remaining in the processing space 20 may be exhausted through a gap between the inner wall of the top plate member 22 and the sidewall of the table 2.

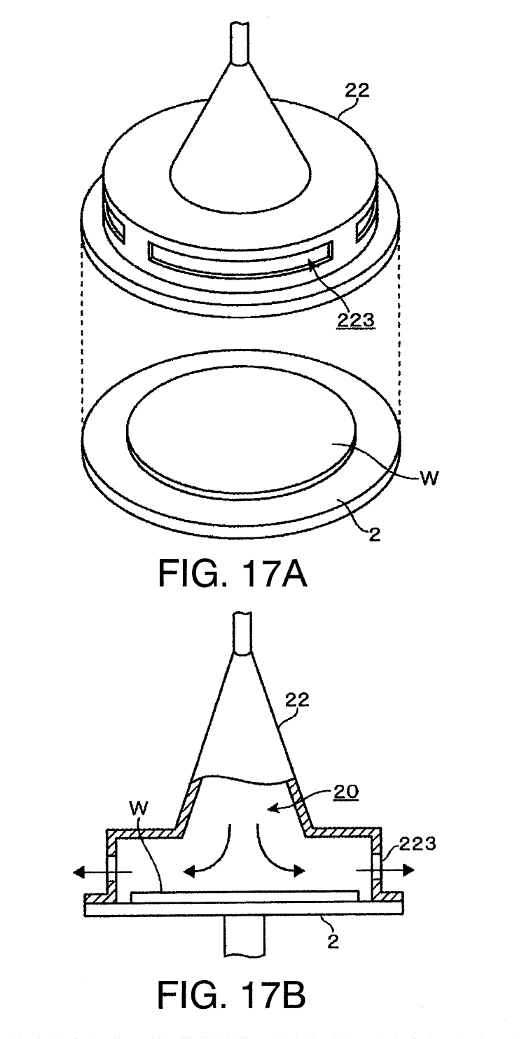

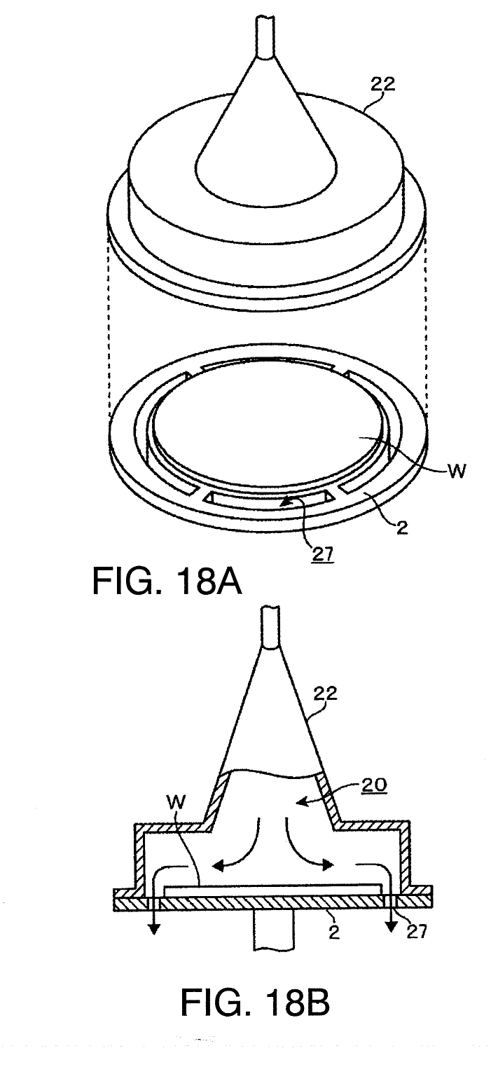

Furthermore, the exhaust openings, through which the reactive gases, etc. in the processing spaces 20 are exhausted toward the exhaust space 10, are not limited to the gaps between the tables 2 and the top plate members 22 in the film deposition system described above. For example, as shown in FIG. 17A and FIG. 17B, the top plate member 22 may be in the shape of a flat cylinder with an open base and have openings 223 e.g., in its periphery. The reactive gases, etc. remaining in the processing space 20 are exhausted through these openings 223 toward the exhaust space 10. Another possible case is that openings 27 are made in a region surrounding the wafer-placing area in the table 2, and the reactive gases, etc. are exhausted through the openings 27 toward the exhaust space 10, as shown in FIG. 18A and FIG. 18B.

As for the reactive gases for use in the film deposition system of the invention, they are not limited to two. The film deposition system of the invention can also be used with an ALD process to deposit films by the use of three reactive gases, as in the case of depositing strontium titanate (SrTiO₃) film, where the reactive gases are Sr(THD)₂ (strontium bis-tetramethylheptanedionate) as a starting material for Sr, Ti(OiPr)₂(THD)₂ (titanium bis-isopropoxide bis-tetramethylheptanedionate) as a starting material for Ti, and an ozone gas as an oxidizing gas, for example. In this case, among the three reactive gases to be supplied to the processing spaces 20 one after another, one of the two depositing material gases to be supplied successively is understood as the first reactive gas, and the other as the second reactive gas. Namely, in the case where the reactive gases are supplied in the order of Sr(THD)₂ gas→Ti(OiPr)₂(THD)₂ gas→ozone gas (explanation is omitted about supply of purge gas), as for the relationship between Sr(THD)₂ gas and Ti(OiPr)₂(THD)₂ gas, the former is the first reactive gas and the latter the second reactive gas; as for the relationship between Ti(OiPr)₂(THD)₂ gas and ozone gas, the former is the first reactive gas and the latter the second reactive gas; and as for the relationship between ozone gas and Sr(THD)₂gas, the former is the first reactive gas and the latter the second reactive gas. The same rule applies to cases where four or more reactive gases are used for film deposition.

The above-described film deposition system, in which the wafer W processing spaces 20 are formed by placing the top plate members 22 having the concavities and the tables 2 so that they face each other, and the pressure in the processing spaces 20 and the residence time of the reactive gases in the processing spaces 20 are controlled by changing the widths (heights) of the gaps between the top plate members 22 and the tables 2, can be used not only for a so-called ALD process but also for other processes. The film deposition system of the invention can also be used for e.g., a CVD (Chemical Vapor Deposition) process which reactive gases are continuously supplied to the processing spaces 20 in order to deposit films on wafer W surfaces. Even in this case, the effect of restraining reactive gas consumption can be obtained.

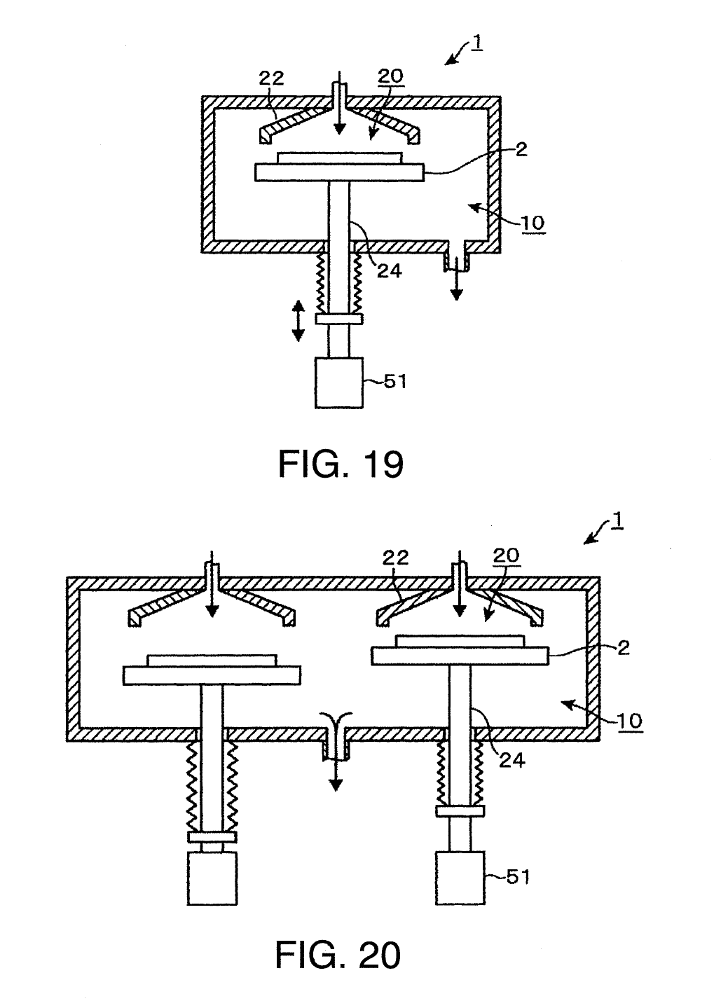

The film deposition system, in which the table 2, lower member, and the top plate member 22, upper member, are so placed that they face each other to form the processing space 20 between them in the vacuum vessel 1, and the two members 2, 22 are so made that they are freely ascendable and descendable in order to make it possible to adjust the width of the gap, which functions as an exhaust opening, between the table 2 and the top plate member 22, is not limited to the embodiment which a plurality of pairs of the table 2 and the top plate member 22 are placed in the vacuum vessel 1 and the widths of the gaps between the two members 2, 22 are adjusted to equal. For example, a film deposition system comprising only one pair of the table 2 and the top plate member 22 in the vacuum vessel 1, as shown in FIG. 19, is also included in the scope of the present invention. Further, even in the film deposition system comprising a plurality of pairs of the table 2 and the top plate member 22 in the vacuum vessel 1, each table 2 may be made ascendable independently in order that the gaps between the top plate members 22 and the tables 2 that constitute the processing spaces 20 can be adjusted to have different widths, as shown in FIG. 20. In this case, it is also possible to deposit films different in film quality in different processing spaces 20 by varying e.g., the residence time or pressure of each reactive gas by adjusting the processing spaces 20 to have different gap widths. Moreover, when depositing different types of films in different processing spaces 20 by supplying different reactive gases, each table 2 can be raised or lowered so that the width of each gap is suited to the reactive gas to be supplied.

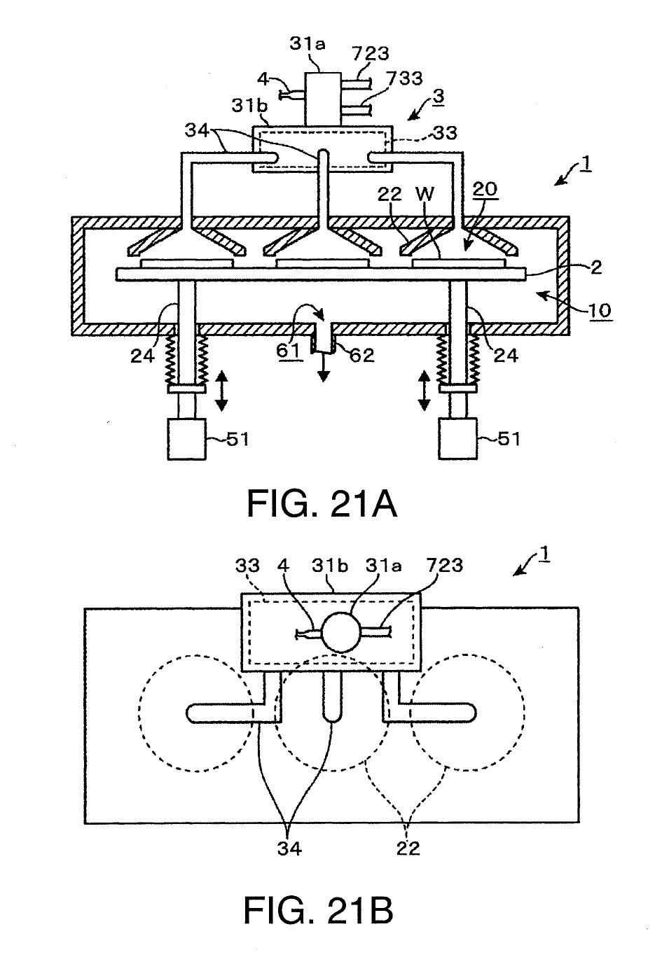

As for the structure of the manifold unit 3, it may also have a structure capable of supplying a gas to a plurality of processing spaces 20 formed in a row in the horizontal direction, as shown in FIG. 14A and FIG. 14B. FIG. 21A and FIG. 21B show an example of such a manifold unit 3. In this manifold unit 3, a gas diffusion chamber 33 is so made that it extends along the row of the processing spaces 20.

Incidentally, the atmospheres in the processing spaces 20, to which gases are supplied from the manifold unit 3, may be airtightly isolated from one another. Namely, the manifold unit 3 may have such a structure that it can supply each gas to a plurality of vacuum vessels. Further, in the above-described examples, although the manifold unit 3 is located in the film deposition system, it may be placed in a gas processing system of other type that is used for conducting another process with a gas under a vacuum, such as ashing, etching, oxidation or nitrification. Furthermore, the substrates to be processed in the aforementioned film deposition system of the invention are not limited to semiconductor wafers W, and other substrates such as FPD (flat panel display) substrates represented by substrates for LCDs (liquid crystal displays), and ceramics substrates may also be used.

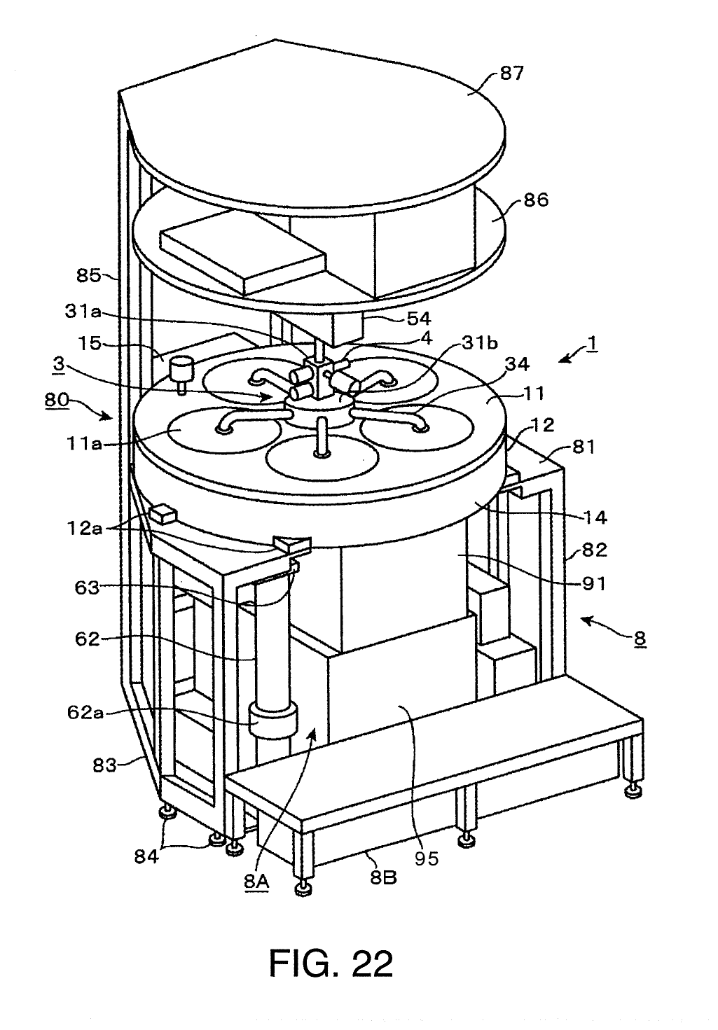

Next, the film deposition system shown in FIG. 1, installed in a plant in an air environment, will be described with reference to FIG. 22 that shows the structure of the system viewed from the outside. The film deposition system is supported on a flat floor surface 8C, with the sidewall 12 and the top plate 11 that constitute the vacuum vessel 1 of the film deposition system being supported by a supporting member 8. The film deposition system supported by the supporting member 8 will be hereinafter referred to as the film deposition system 80.

The supporting member 8 comprises a supporting base 81, supporting legs 82, horizontal members 83 and fixing members 84. The bottom end of the sidewall 12 of the vacuum vessel 1 has projections 12a extending outward, situated in the circumferential direction at intervals. The supporting base 81 is situated along the periphery of the vacuum vessel 1 and supports the projections 12a at their back. The supporting base 81 is so made that it does not interfere with the base plate 14 of the vacuum vessel 1 when the base plate 14 is lowered and separated from the sidewall 12, as will be described later.

In the film deposition system 80, suppose the side in which the transportation opening 15 is provided is the rear side. The supporting base 81 has a plurality of supporting legs 82 at its right and left edges, arranged at intervals beginning from the front to the rear side. Each supporting leg 82 extends downward. A horizontal member 83 extending from the front to the rear side connects the supporting legs 82 situated on the left of the vacuum vessel 1 at their bottom ends, and another horizontal member 83 connects the supporting legs 82 situated on the right of the vacuum vessel 1 at their bottom ends. A plurality of fixing members 84 for fixing the supporting legs 82 and the horizontal members 83 to the floor surface 8C are attached to the underside of the horizontal members 83 and also to the bottom ends of the supporting legs 82 at intervals.

On the rear side, the supporting legs 82 situated on the left and the right sides extend above the supporting base 81, and the extensions constitute supporting posts 85. The supporting posts 85 support a supporting plate 86 and a top plate 87 situated above the supporting plate 86. On top of the supporting plate 86 are located devices such as a power source unit for the film deposition system. Further, although not shown in the figure, the film deposition system 80 is surrounded by detachable side plates, which prevent, together with the top plate 87, particles from entering the film deposition system 80.

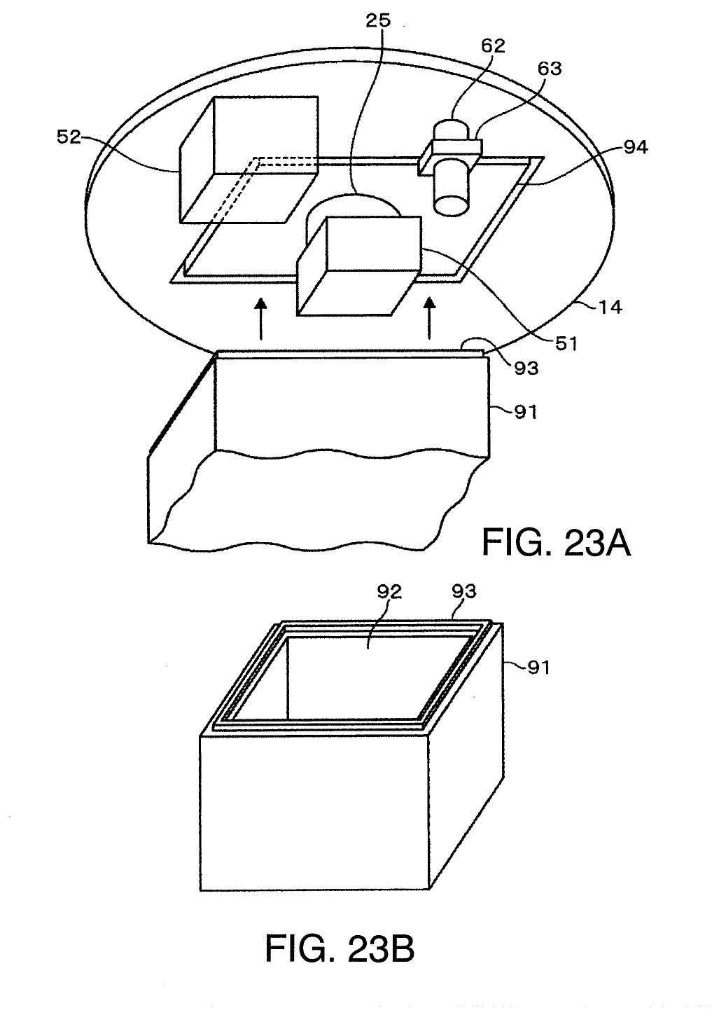

In the space 8A under the vacuum vessel 1, surrounded by the supporting legs 82 and the horizontal members 83, a holding member 91 for holding the base plate 14 of the vacuum vessel 1 from its back is located. FIG. 23A shows the back of the base plate 14, and FIG. 23B the top of the holding member 91. As shown in FIG. 23B, the holding member 91 has a tubular cavity 92 that surrounds the sleeve 25 and the driving unit 51. The holding member 91 has a raised portion 93 at its top end along its edge, and the base plate 14 has, on its back, a groove 94 in such a shape that the raised portion 93 can be fit into it and that it surrounds the sleeve 25 and the driving unit 51 extending downward from the center of the base plate 14. Since the raised portion 93 fits into the groove 94, positioning of the holding member 91 is done relative to the base plate 14.

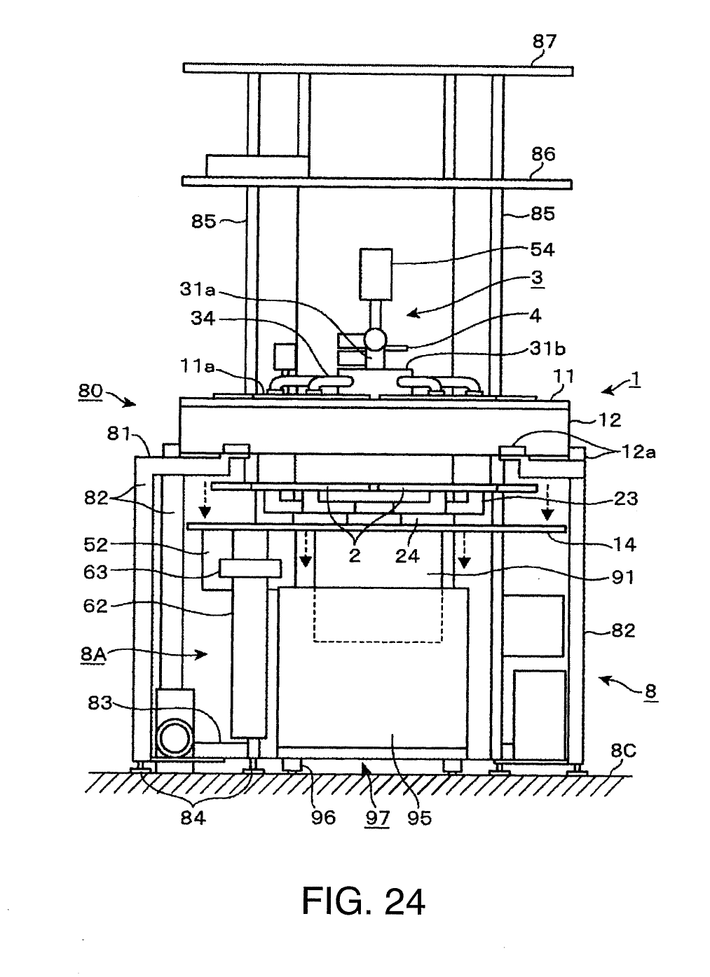

Under the holding member 91 is located an elevating mechanism 95. The elevating mechanism 95 has an oil pressure cylinder for vertically raising or lowering e.g., the holding member 91. As the holding member 91 is raised or lowered, the base plate 14 of the vacuum vessel 1 and the tables 2 disposed on the base plate 14 through the support column 24 is also raised or lowered. Further, as shown in FIG. 24, a carriage 97 having casters 96, as rolling elements, is located under the elevating mechanism 95. The carriage 97 as a movable body allows the elevating mechanism 95 to move on the floor surface 8C. As the elevating mechanism 95 moves, the holding member 91 can also move on the floor surface 8C. Namely, the elevating mechanism 95, the holding member 91, and the base plate 14 can move on the floor surface 8C, with their positional relationship retained.

Into the space 8A under the vacuum vessel 1, an exhaust pipe 62 connected to the base plate 14 of the vacuum vessel 1 is lead. In the figure, reference numeral 62a designates a joint that connects the upstream portion and the downstream portion of the exhaust pipe 62. In front of the space 8A is located a footstool 8B on which a user can stand in order to operate each unit of the film deposition system.

Next, the procedure for maintenance of the aforementioned film deposition system 80, which is carried out with the vacuum vessel 1 in the system 80 opened, will be described. After terminating the film deposition by stopping the gas supply to the processing spaces 20 and the evacuation of the processing spaces 20, the footstool 8B is moved from the front of the space 8A to e.g., the left or the right side, thereby forming an open space in front of the space 8A. The upstream portion of the exhaust pipe 62, connected to the joint 62a, is removed from the joint 62a. The joint 62a and the downstream portion of the exhaust pipe 62, connected to the joint 62a, are moved to a proper position so that the upstream portion of the exhaust pipe 62, which is lowered as the base plate 14 is lowered, does not interfere with them.

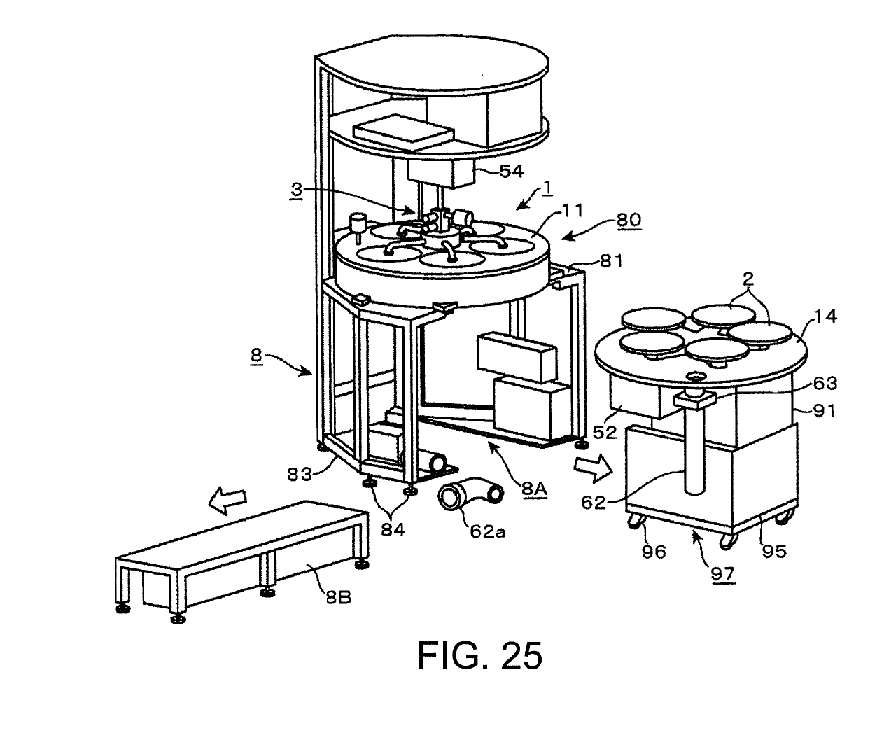

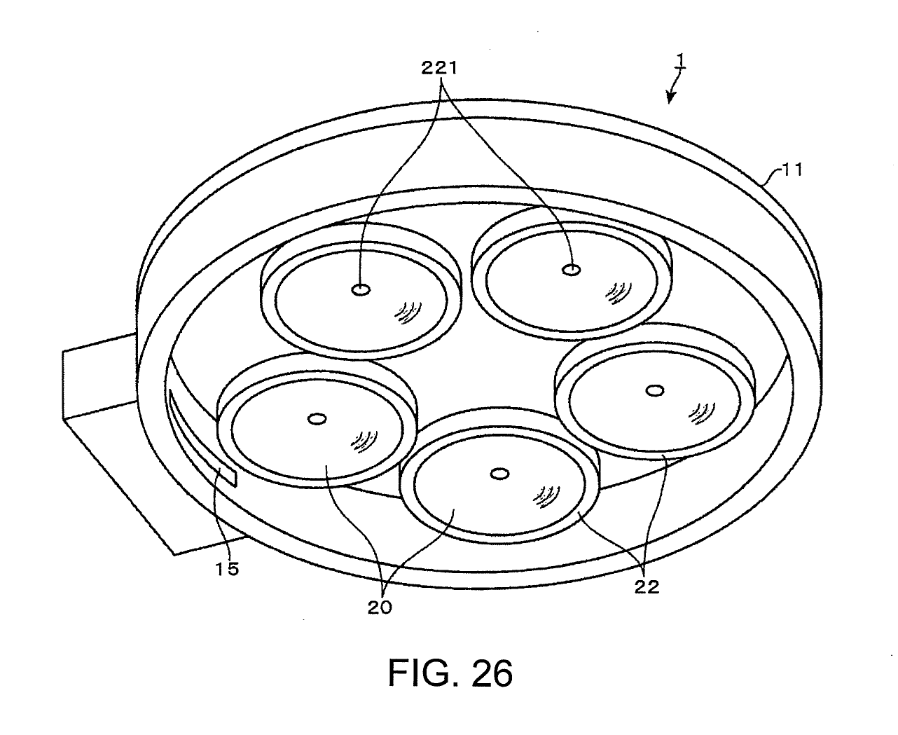

After this, fasteners such as screws connecting the base plate 14 with the sidewall 12, not shown in the figure, are removed, and the base plate 14 of the vacuum vessel 1 is lowered by means of the elevating mechanism 95 via the holding member 91, thereby lowering the tables 2 connected to the base plate 14 to such a position that the height of the top of the tables 2 is lower than the bottom end of the supporting base 81 supporting the sidewall 12, as shown in FIG. 24. The elevating mechanism 95 and the holding member 91 are drawn out of the space 8A under the vacuum vessel 1 by the carriage 97, as shown in FIG. 25. With this movement of the elevating mechanism 95 and the holding member 91, the base plate 14, the tables 2, the supporting arms 23, the support column 24 and the upstream portion of the exhaust pipe 62 are drawn out of the space 8A.

The user can manually wipe the base plate 14 and the other components which have been drawn out of the space 8A, or can disassemble the drawn-out components and clean the same with a predetermined cleaning apparatus, thereby removing the deposits formed by the reactive gases. After the base plate 14 has been removed from the vacuum vessel 1, the bottom of the vacuum vessel 1 is open to the space 8A, as shown in FIG. 26. It is also possible for the user to remove the deposits formed by the reactive gases by manually wiping the components of the vacuum vessel 1 from its open bottom via the under space 8A, or by cleaning, with a predetermined cleaning apparatus, the components taken out of the vacuum vessel 1 through its open bottom via the under space 8A. Besides such cleaning operations, the user can carry out various maintenance operations such as replacement of any defective component.

After the completion of the maintenance operations, the base plate 14 is attached to the bottom of the vacuum vessel 1, following the procedure reverse to the one for removing the base plate 14 from the vacuum vessel 1, thereby returning the film deposition system 80 to the state before the start of the maintenance operations.

Like a conventional film deposition system, it is also possible to open the top of the vacuum vessel 1 in the film deposition system 80 by removing the top plate 1 from the sidewall 12. Further, the top plate 11 has removable cover members 11a in the positions corresponding to the respective processing spaces 20, and the bottoms of the cover members 11a are connected to the top plate members 22 that form the processing spaces 20, so that the top plate members 22 can be drawn out of the vacuum vessel 1 together with the cover members 11a. The inside of the vacuum vessel 1 can be cleaned in the above-described manner after exposing the tables 2 by drawing (taking) out the cover members 11a and the top plate members 22. It is necessary that before taking out the top plate 11 and the cover members 11a, the liquid depositing material and the reactive gases be removed from the supply pipes and that the gas supply pipes 34 be detached from the top plate 11. Possible cases where the maintenance operation is carried out after taking out the top plate 11 and the cover members 11a are, e.g., the case where the products cannot fully be wiped off with the user's hand from the open bottom of the vacuum vessel 1, and the case where any component has to be replaced.

The film deposition system 80 as an embodiment of vacuum processing system comprises the base plate 14 of the vacuum vessel 1, that has the tables 2 on which wafers W will be placed and that is detachable from the top plate 11 and the sidewall 12 of the vacuum vessel 1; the elevating mechanism 95 for raising and lowering the base plate 14; and the carriage 97 capable of moving, on the floor surface 8C, the elevating mechanism 95 located on the carriage 97, so that it is possible to remove the base plate 14 and the tables 2 from the sidewall 12 and to move the base plate 14 and the tables 2 to their corresponding position where the maintenance operation for the side wall 12, the base plate 14 and the table 2 can be carried out. It is therefore unnecessary to remove the top plate 11 from the vacuum vessel 1, and thus unnecessary to remove the liquid depositing material and the reactive gases from the respective supply pipes through which they are supplied to the manifold unit 3. This makes it easy to carry out the system maintenance operations.

Incidentally, if a plurality of units are prepared, each unit being composed of the holding member 91, the elevating mechanism 95, the tables 2 and the base plate 14, which are moved in and out of the space 8A as described above, while carrying out the maintenance operation for one of the plurality of units, a film deposition is conducted with another unit attached to the vacuum vessel 1, so that reduction in the operating efficiency of the system that is caused by the above-described maintenance operation can be inhibited.

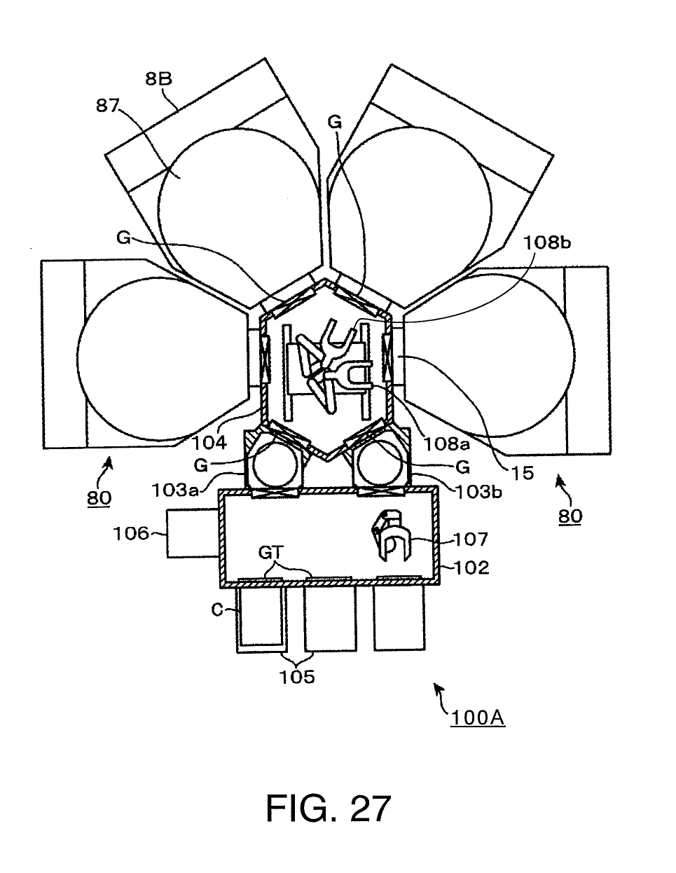

With reference to FIG. 27, the structure of a semiconductor production system 100A comprising four of the film deposition systems 80 as described above will now be described. The semiconductor production system 100A comprises a first transportation chamber 102 that constitutes a loader module for loading and unloading wafers W, load-lock chambers 103a, 103b, and a second transportation chamber 104 that is a vacuum transportation chamber module. Load ports 105 on which carriers C are placed are disposed in front of the first transportation chamber 102, and the front wall of the first transportation chamber 102 has gate doors GT to which carriers C placed on the load ports 105 are to be connected and which are opened or closed together with the covers of the carriers C. To the second transportation chamber 104 are airtightly connected the four of the film deposition systems as described above.

On its side, the first transportation chamber 102 is provided with an alignment chamber 106 in which wafers W are oriented to a proper direction and also centered. Each load-lock chamber 103, 103b has a vacuum pump and a leak valve, not shown in the figure, so that the atmosphere therein can be changed from air to vacuum, and vice versa. Namely, since the atmosphere in the first transportation chamber 102 and that in the second transportation chamber 104 are kept aerial and vacuum, respectively, the load-lock chambers 103a, 103b serve to control atmospheres therein during transportation of wafers W between the two transportation chambers 102, 104. In the figure, symbol G designates gate valves for isolating the load-lock chambers 103a, 103b from the first transportation chamber 102 or the second transportation chamber 104, or for isolating the second transportation chamber 104 from the transportation opening 15 in the film deposition systems 80.

The first transportation chamber 102 has a first transportation unit 107. The second transportation chamber 104 has second transportation units 108a, 108b. The first transportation unit 107 is a carrying arm for making delivery of a wafer W among the carrier C, the load-lock chambers 103a, 103b, and the alignment chamber 106. The second transportation units 108a, 108b are carrying arms for making delivery of a wafer W between the load-lock chambers 103a, 103b and the film deposition systems.

As for operation of the system, the carriers C are first transported to the semiconductor production system 100A, are placed on the load ports 105, and are connected to the first transportation chamber 102. Subsequently, the gate doors GT and the covers of the carriers C are opened simultaneously, and the wafers W on the carriers C are transported in the first transportation chamber 102 by the first transportation unit 107. The wafers W are transported to the alignment chamber 106, in which they are oriented to a proper direction and also centered. After this, the wafers W are transported to the load-lock chamber 103a (or 103b). After the pressure in the load-lock chamber 103a (103b) has been adjusted, the wafers W are transported from the load-lock chamber 103a (103b) to the second transportation chamber 104 by the second transportation unit 108a (108b). Subsequently, the gate valves G on the film deposition systems 80 are opened, and the wafers W are transported to the film deposition systems 80 by the second transportation unit 108a (108b).

After the film deposition has been completed in the film deposition systems 80, the gate valves G on the film deposition systems 80 are opened, and the second transportation unit 108a (or 108b) comes in the vacuum chambers 1 in the film deposition systems 80. The wafers W processed in the above-described manner are delivered to the second transportation unit 108a (or 108b), and then the second transportation unit 108a (or 108b) delivers the wafers W to the first transportation unit 107 via the load-lock chamber 103a (or 103b). The first transportation unit 107 returns the wafers W to the carriers C.

1. A film deposition system which a cycle of alternately supplying a first reactive gas and a second reactive gas and exhausting them is repeated twice or more in a vacuum vessel to cause reaction between the two gases, thereby depositing thin films on substrate surfaces, the film deposition system comprising in the vacuum vessel:
a plurality of lower members having substrate-placing areas on which substrates will be placed,
a plurality of upper members so placed that they face the lower members to form processing spaces together with the substrate-placing areas,
a first reactive gas supply unit and a second reactive gas supply unit for supplying a first reactive gas and a second reactive gas, respectively, to the processing spaces,
a purge gas supply unit for supplying a purge gas in the period between a first reactive gas supply period and a second reactive gas supply period,
exhaust openings, situated along circumferences of the processing spaces, for communicating the inside of the processing spaces with the atmosphere in the vacuum vessel that is outside of the processing spaces, and
an evacuating unit for evacuating the processing spaces via the atmosphere in the exhaust openings and the vacuum vessel.

2. The film deposition system according to claim 1, wherein the upper member has an inner surface whose transversal section is increased from the top to the bottom.

3. The film deposition system according to claim 1, wherein the exhaust opening is a gap circumferentially formed between a bottom edge of the upper member and the lower member.

4. The film deposition system according to claim 1, wherein the upper member has, in its center, a gas supply opening through which the first reactive gas, the second reactive gas, and the purge gas are supplied.

5. The film deposition system according to claim 1, wherein a plurality of pairs of the upper and the lower members are circumferentially arranged in the vacuum vessel.

6. The film deposition system according to claim 5, further comprising a common rotating unit for integrally rotating the pairs of the upper and the lower members that are circumferentially arranged in the vacuum vessel, in the circumferential direction so that delivery of a substrate can be made between a substrate transportation unit located outside the vacuum vessel and the substrate-placing area through a delivery opening provided in a sidewall of the vacuum vessel.

7. The film deposition system according to claim 1, further comprising an elevating unit for raising and lowering the lower member relative to the upper member in order to form a space necessary for delivery of a substrate between a substrate transportation unit located outside the vacuum vessel and the substrate-placing area.

8. The film deposition system according to claim 7, wherein the elevating unit is a common one to be used for all the lower members.
